(19) United States
(12) Patent Application Publication
(10) Pub. No.: US 2026/0068256 A1
(43) Pub. Date: Mar. 5, 2026

(54) ISOLATION STRUCTURE IN SEMICONDUCTOR DEVICE AND METHOD FOR MANUFACTURING SAME

(71) Applicant: Taiwan Semiconductor Manufacturing Company, Ltd., Hsin-Chu (TW)

(72) Inventors: Ming-Heng Tsai, Hsinchu (TW); Chun-Sheng Liang, Hsinchu (TW)

(21) Appl. No.: 18/821,777

(22) Filed: Aug. 30, 2024

(51) Int. Cl. H01L 29/66; H01L 21/8234; H01L 27/088; H01L 29/06; H01L 29/423; H01L 29/775; H01L 29/786

(52) U.S. Cl. CPC H10D 64/017; H10D 30/014; H10D 30/43; H10D 30/6735; H10D 30/6757; H10D 62/115; H10D 62/121; H10D 64/015; H10D 84/0128; H10D 84/013; H10D 84/038; H10D 84/83

(57) ABSTRACT

A method of the present disclosure includes forming a fin-shaped structure protruding from a substrate, depositing an isolation feature on sidewalls of the fin-shaped structure, forming a dummy gate stack over a portion of the fin-shaped structure, removing a portion of the dummy gate stack to form a trench exposing the portion of the fin-shaped structure, recessing the portion of the fin-shaped structure to extend the trench downward below a top surface of the isolation feature, depositing a first dielectric layer in the trench, recessing the first dielectric layer, such that a topmost portion of the first dielectric layer is below the top surface of the isolation feature, after the recessing of the first dielectric layer, depositing a second dielectric layer in the trench, the first and second dielectric layers including different material compositions, and replacing an unremoved portion of the dummy gate stack with a metal gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

As GAA devices continue to scale, various challenges have arisen. For example, to maintain the desired scaling and increased density for GAA devices in advanced technology nodes, a cut-poly (CPO) process may be employed to create an isolation structure (also referred to as a CPO structure or a CPO feature) that supports the continued reduction of the contacted poly pitch (CPP) (or “gate pitch”). In at least some implementations, a CPO feature includes an oxide liner as an insulator to suppress charge accumulation at the boundary between the n-type well and the p-type well. However, in some cases, the oxide liner in the CPO feature may be damaged during a replacement gate process. Therefore, although existing structures and fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-29 illustrate fragmentary top and cross-sectional views of a work-in-progress (WIP) structure during a fabrication process according to the method of FIG. 1, according to one or more aspects of the present disclosure.

FIGS. 30-39 illustrate fragmentary top and cross-sectional views of various alternative embodiments of a semiconductor device at the conclusion of a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art.

The present disclosure is generally related to GAA transistors and manufacturing methods thereof. Embodiments of the present disclosure offer advantages over the existing art, though it is understood that other embodiments may offer different advantages, not all advantages are necessarily discussed herein, and no particular advantage is required for all embodiments. For example, embodiments discussed herein include isolation structures and related methods to isolate adjacent metal gate structures.

Continuing to provide the desired scaling and increased density for GAA devices in advanced technology nodes calls for scaling of the contacted poly pitch (CPP) (or “gate pitch”). In some embodiments of the present disclosure, a cut-poly (CPO) process is used to scale the CPP. The CPO process may provide an isolation structure (also referred to as a CPO structure or a CPO feature) between neighboring gate structures, and thus neighboring transistors, by performing a selective etching process along an active edge (e.g., at a boundary of adjacent active regions) to form a cut region and filling the cut region with dielectric material(s). An active region includes a region where transistor structures are formed (e.g., including channel, source, and drain). In some examples, an active region may have a fin-like shape protruding from a substrate and may be disposed between insulating regions (e.g., shallow trench isolation (STI) regions). The CPO feature prevents adjacent metal gate structures from merging. In some implementations, the CPO feature may have an oxide liner. When the CPO feature is disposed over a boundary between an n-type well (or termed as n-well) and a p-type well (or termed as p-well), the oxide material in the oxide liner may function as an insulator to suppress accumulation of charges (e.g., holes and/or electrons) at the boundary between the wells of opposite conductivity types. However, a replacement gate process may expose and etch the oxide liner of the CPO feature and thus cause damage to the CPO feature.

GAA transistors may be fabricated using a replacement gate process, where a dummy gate stack is formed first as a placeholder and is subsequently replaced with a functional gate structure. In some replacement gate processes, sacrificial materials among nanostructures of the GAA transistor are removed after epitaxial source/drain features are formed. Ideally, due to the different material compositions, a large etch selectivity between the sacrificial materials (e.g., SiGe) and the nanostructures (e.g., Si) should have safeguarded the nanostructures from etching loss during the removal of the sacrificial materials. However, atoms other than silicon (e.g., Ge) in the sacrificial materials may diffuse into the nanostructures as impurities during annealing processes, such as the annealing processes in forming the epitaxial source/drain features. The diffusion of the impurities lowers the etching selectivity. As a result, the nanostructures may suffer from etching loss during the removal of the sacrificial materials. For example, top and bottom surfaces of the nanostructures may become non-flat and have a curvature profile due to extra etching loss. The curvature profile of the top and bottom surfaces of the nanostructures may cause gate structure profile variation and result in device performance non-uniformity.

To improve uniformity of the surface profiles of the nanostructures and gate structures, one way is to replace the sacrificial layers with a dielectric dummy layer that exhibits higher etching contrast with respect to the nanostructures prior to the replacement gate process. In an example process, a fin-shaped structure with channel layers and sacrificial layers is formed over a substrate. After formation of a dummy gate stack over a channel region of the fin-shaped structure, at least one gate spacer is formed over the dummy gate stack. Source/drain regions of the fin-shaped structure are recessed. The sacrificial layers are selectively removed to release the channel layers as channel members. A dielectric dummy layer is then deposited to wrap around each of the channel members. The dielectric dummy layer is then selectively and partially recessed to form inner spacer recesses between the plurality of channel members. An inner spacer layer is deposited over the inner spacer recesses. The deposited inner spacer layer is etched back to form inner spacers. Source/drain features are then formed over the source/drain recesses. After selective removal of the dummy gate stack, the dielectric dummy layer is selectively removed to release the channel members again. A metal gate structure is then formed to wrap around each of the channel members. To improve the etching contrast, the dielectric dummy layer may be formed of an oxide. If the CPO feature includes an oxide liner, the selective removal of the dummy gate stack would expose the oxide liner of the CPO feature, and the subsequent selective removal of the dielectric dummy layer would also etch the oxide liner of the CPO feature. The damage of the oxide liner of the CPO feature may lead to metal gate protrusion and cause a short circuit between subsequently-formed metal gate structure and adjacent source/drain features and contacts.

Embodiments of the present disclosure offer a multi-layer (e.g., bi-layer or tri-layer) CPO feature with an oxide material disposed at the bottom portion of the CPO feature. The oxide material is positioned sufficiently low such that it would not be exposed during a replacement gate process. Thus, the integrity of the CPO feature is improved.

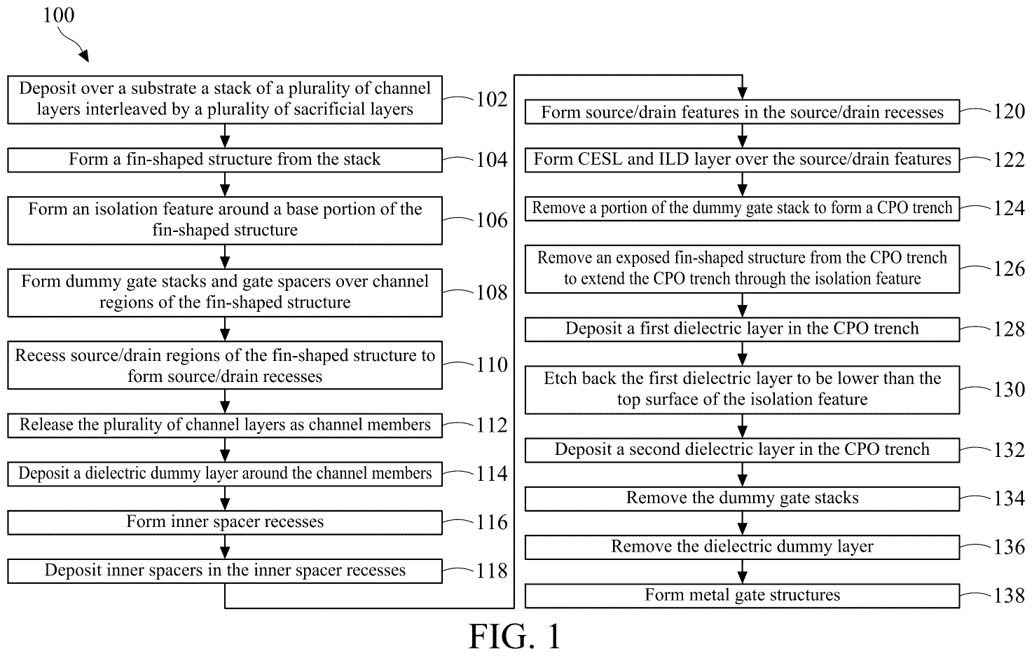

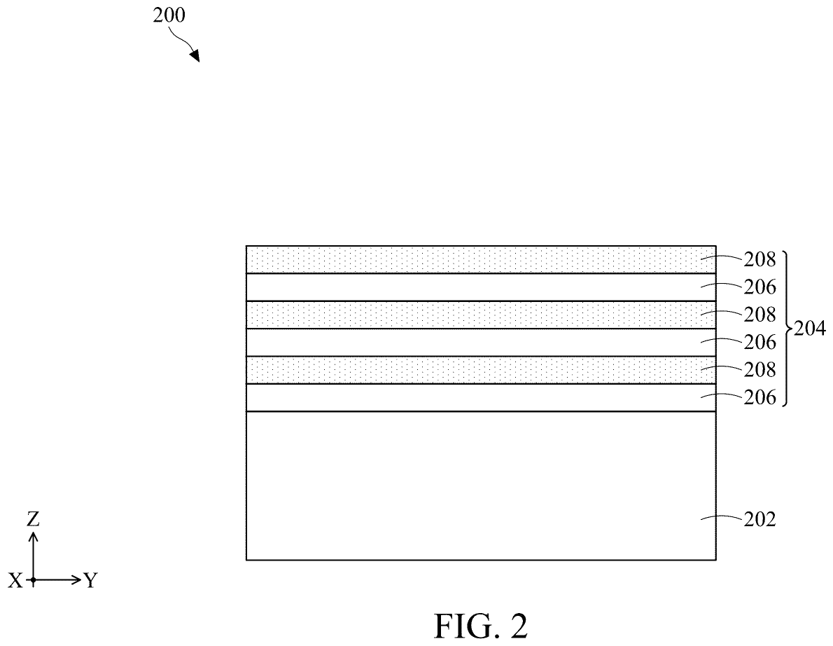

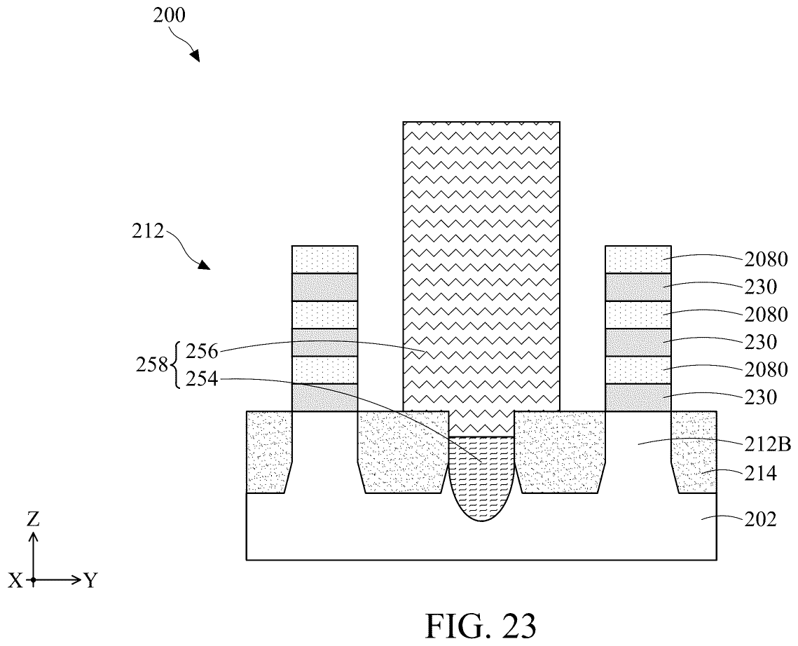

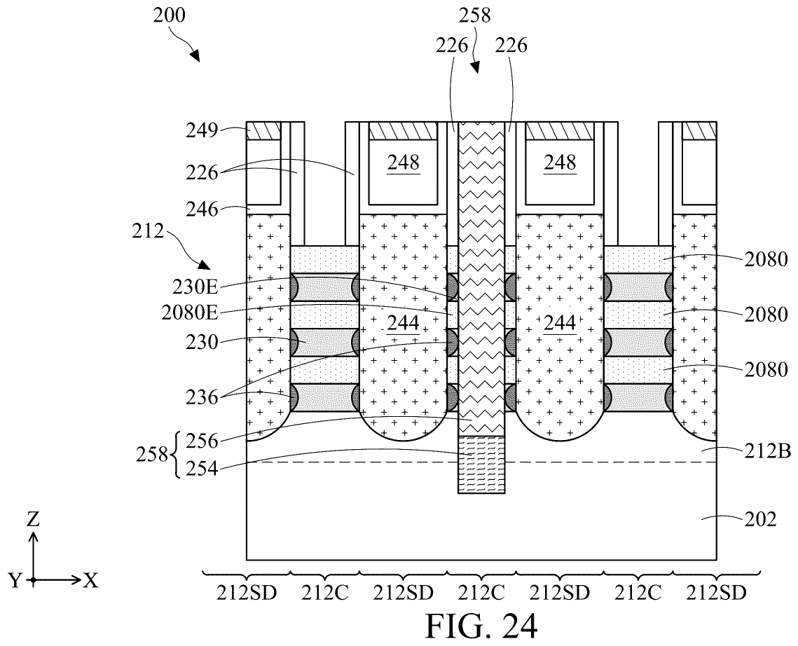

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-38, which are fragmentary top and cross-sectional views of a WIP structure 200 at different stages of fabrication according to embodiments of the method 100 in FIG. 1. Because the WIP structure 200 will be fabricated into a semiconductor structure or a semiconductor device, the WIP structure 200 is also referred to herein as a semiconductor structure 200 or a semiconductor device 200. For avoidance of doubts, the X, Y and Z directions in FIGS. 2-38 are perpendicular to one another. Throughout the present disclosure, unless expressly described otherwise, like reference numerals denote like features or steps.

Referring to FIGS. 1 and 2, method 100 includes a block 102 where a stack 204 of alternating semiconductor layers is formed over the semiconductor device 200. As shown in FIG. 2, the semiconductor device 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the performance needs for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, Ge % in the sacrificial layers 206 may be not less than about 20%, such as about 30% or above. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

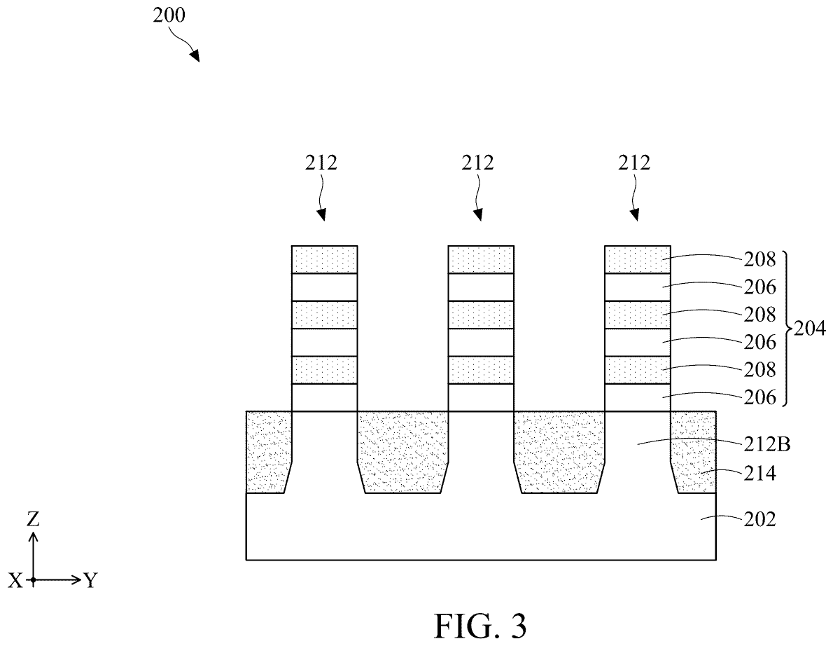

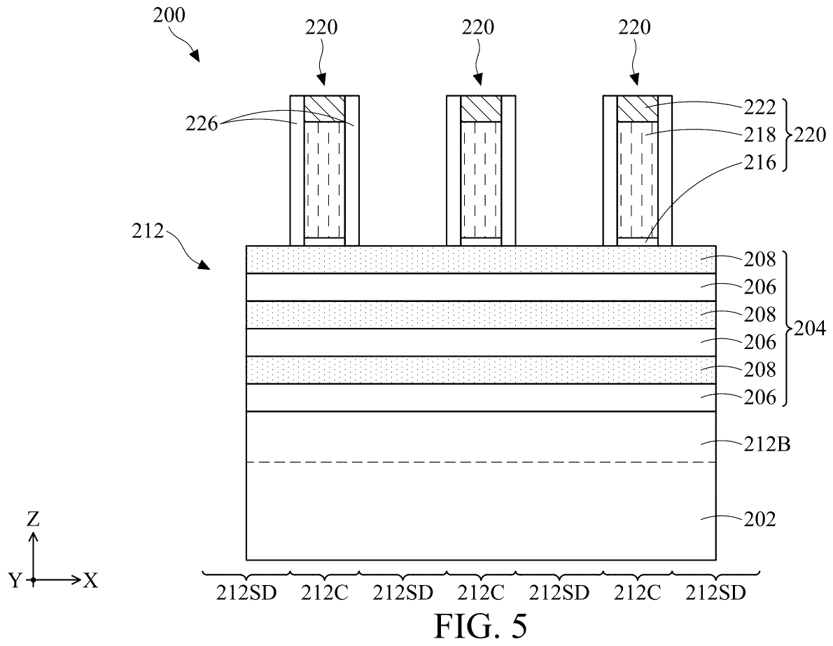

Referring to FIGS. 1 and 3, method 100 includes a block 104 where fin-shaped structures 212 are formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structures 212 may be patterned from the stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. As shown in FIG. 3, the etching process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 extends vertically along the Z direction and lengthwise along the Y direction. The fin-shaped structure 212 provides an active region (also termed as active region 212) for the subsequently-formed transistors, which includes channel regions (denoted as 212C, as shown in FIG. 5) and source/drain regions (denoted as 212SD, as shown in FIG. 5). As shown in FIG. 3, the fin-shaped structure 212 includes a fin-shaped base 212B patterned from the substrate 202 and the patterned stack 204 disposed directly over the fin-shaped base 212B. In the illustrated embodiment as shown in FIG. 3, the patterned stack 204 and the top portion of the fin-shaped base 212B have substantially straight sidewalls; while the bottom portion of the fin-shaped base 212B has tapering sidewalls due to loading effect during the patterning process.

Still referring to FIGS. 1 and 3, method 100 includes a block 106 where an isolation feature 214 is formed around the fin-shaped base 212B of the fin-shaped structures 212. In some embodiments represented in FIG. 3, the isolation feature 214 is disposed on sidewalls of the fin-shaped base 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214 or an STI region 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the isolation feature 214 shown in FIG. 3. The fin-shaped structure 212 rises above the isolation feature 214 after the recessing, while the fin-shaped base 212B is embedded or buried in the isolation feature 214.

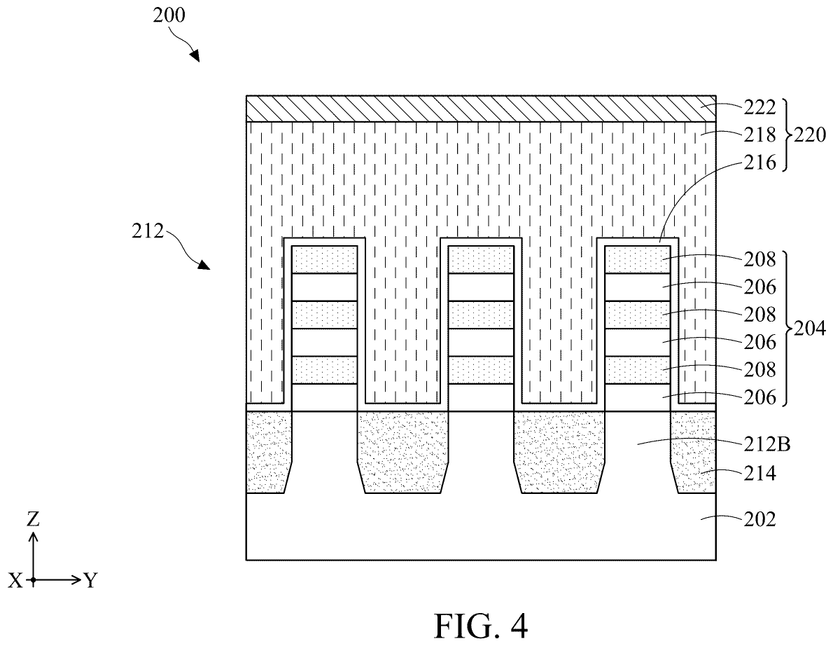

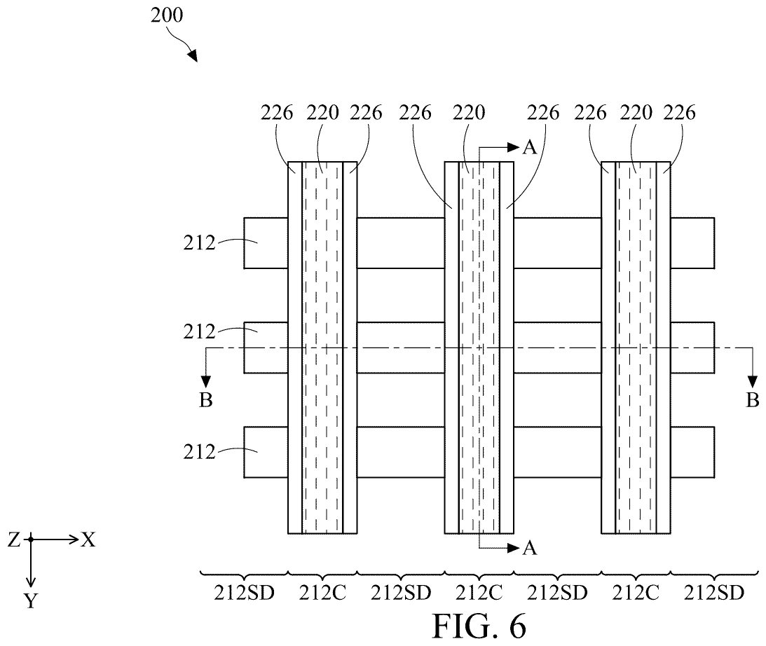

Referring to FIGS. 1 and 4-6, method 100 includes a block 108 where dummy gate stacks 220 and gate spacers 226 are formed over channel regions 212C of the fin-shaped structure 212. The dummy gate stacks 220 serve as a placeholder to undergo various processes and are to be removed and replaced by functional gate structures. Other processes and configuration are possible. FIG. 6 is a fragmentary top view of the semiconductor device 200 at the conclusion of block 108, FIG. 4 is a cross-sectional view along the A-A line in FIG. 6, and FIG. 5 is a cross-sectional view along the B-B line in FIG. 6. As shown in FIG. 5, the dummy gate stacks 220 and gate spacers 226 are formed over the fin-shaped structure 212, and the fin-shaped structure 212 may be divided into channel regions 212C underlying the dummy gate stacks 220 and the gate spacers 226 and source/drain regions 212SD that do not underlie the dummy gate stacks 220 and the gate spacers 226. The channel regions 212C are adjacent to the source/drain regions 212SD. As shown in FIG. 5, the channel region 212C is disposed between two source/drain regions 212SD along the X direction. As used herein, a source/drain region, or “S/D region,” may refer to a region that provides a source and/or drain for one or multiple devices. It may also refer to a source or a drain of one or multiple devices. Also, in FIG. 5 (as well as in following figures showing the cross-sectional view in the X-Z plane), a horizontal dotted line marks the position of the bottom surface of the isolation feature 214.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the semiconductor device 200. The dummy dielectric layer 216 may be conformally deposited on the fin-shaped structure 212 using a chemical vapor deposition (CVD) process, an atomic layer deposition (ALD) process, an oxygen plasma oxidation process, or other suitable processes. The term “conformally” may be used herein for ease of description of a layer having substantially uniform thickness over various regions. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stacks 220, as shown in FIG. 5. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 is a bi-layer structure, which may include a silicon oxide layer and a silicon nitride layer over the silicon oxide layer.

The formation of the gate spacers 226 may include deposition of a gate spacer layer and etching back the gate spacer layer. In some embodiments, the gate spacer layer is deposited conformally over the semiconductor device 200, including over top surfaces and sidewalls of the dummy gate stacks 220. The gate spacer layer may be a single layer or a multi-layer. The at least one layer in the gate spacer layer may include silicon carbonitride, silicon oxycarbide, silicon oxycarbonitride, or silicon nitride. The gate spacer layer may be deposited over the dummy gate stack 220 using processes such as, a CVD process, a subatmospheric CVD (SACVD) process, an ALD process, or other suitable process. Subsequently, an anisotropic etching process may be implemented to remove portions of the gate spacer layer from top-facing surfaces of the semiconductor device 200, including from top-surfaces of the dummy gate stacks 220. The remaining portions of the gate spacer layer covers sidewalls of the dummy gate stacks 220 as the gate spacers 226.

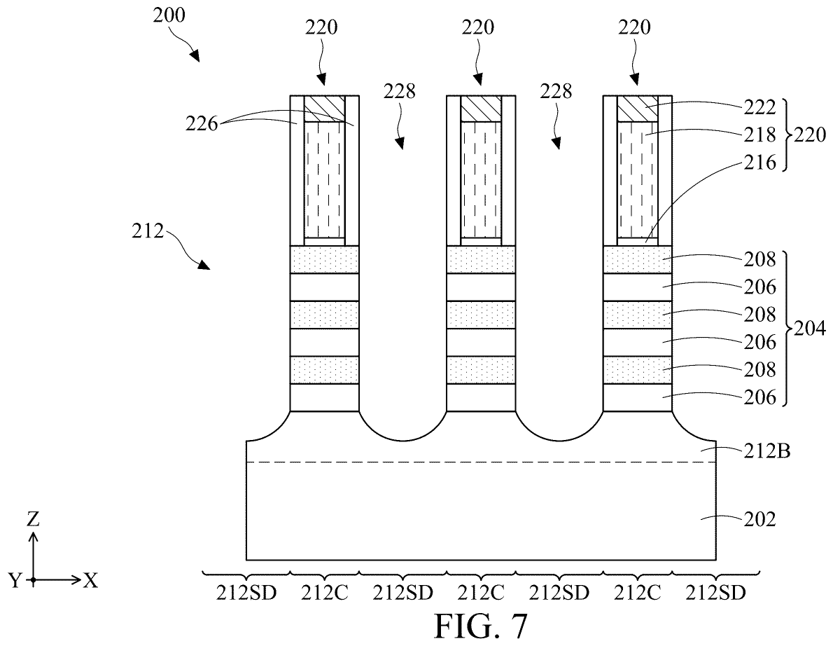

Referring to FIGS. 1 and 7, method 100 includes a block 110 where source/drain regions 212SD of the fin-shaped structure 212 are anisotropically recessed to form source/drain trenches 228. The anisotropic etch may include a dry etch or a suitable etching process that etches the source/drain regions 212SD and a portion of the substrate 202. The resulting source/drain trenches 228 extend vertically through the depth of the stack 204 and partially into the substrate 202. An example dry etching process for block 110 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 7, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

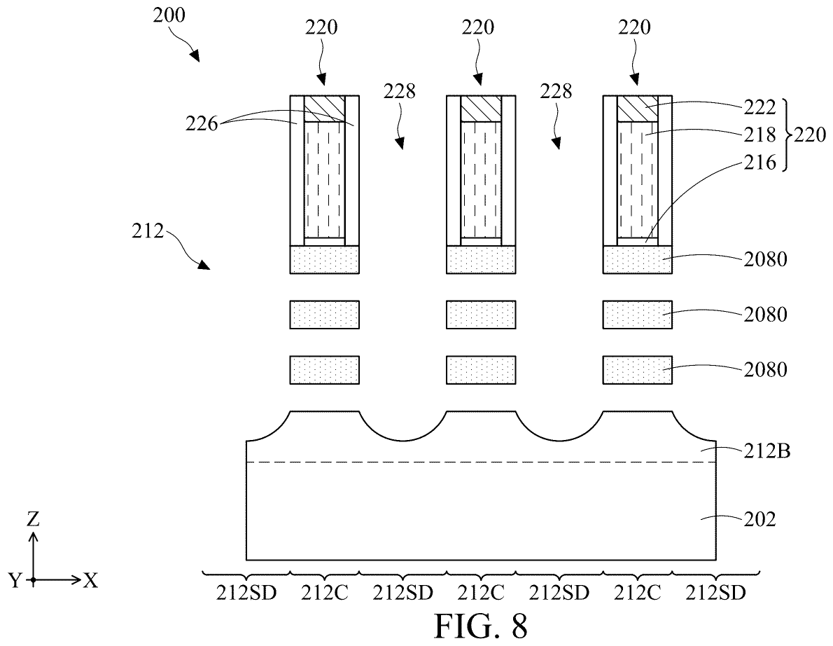

Referring to FIGS. 1 and 8, method 100 includes a block 112 where the plurality of channel layers 208 in the channel regions are released as channel members 2080. After the formation of the source/drain trenches 228, the sacrificial layers 206 interleaving the channel layers 208 in the channel region 212C are selectively removed. The selective removal of the sacrificial layers 206 releases the channel layers 208 to form the channel members 2080. Depending on the design, the channel members 2080 may take form of nanowires, nanorods, nanosheets, or other nanostructures. The selective removal of the sacrificial layers 206 forms spaces between and around adjacent channel members 2080. The selective removal of the sacrificial layers 206 may be implemented by a selective dry etching process. An example selective dry etching process may include use of one or more fluorine-containing (F-containing) gas. In some embodiments, the fluorine-containing gas can include fluorine (F₂), hydrogen fluoride (HF), chlorine trifluoride (ClF₃), fluorine radical (F*), and nitrogen trifluoride radical (NF₃*). The germanium concentration difference between the sacrificial layers 206 and the channel layers 208 provide proper etching selectivity. In some embodiments, the sacrificial layers 206 can be etched by a gas phase etching using fluorine-containing gases, such as F₂, HF, and ClF₃. In some embodiments, the sacrificial layers 206 can be etched by a radical phase etching using radicals, such as F*, H*, and NF₃*, generated from fluorine-containing gases by a remote plasma system. The dry etching process can have by-products, such as silicon tetrafluoride (SiF₄) and germanium tetrafluoride (GeF₄).

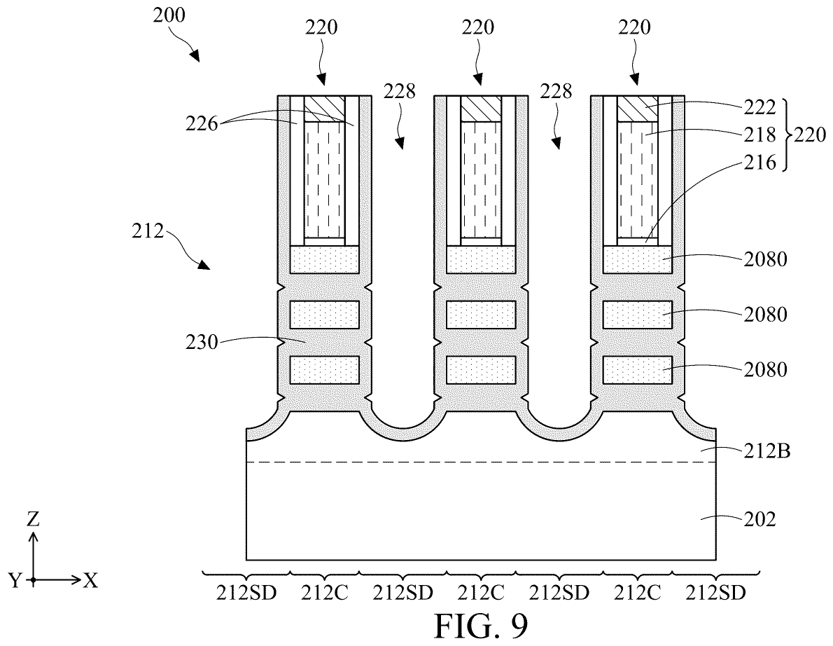

Referring to FIGS. 1 and 9, method 100 includes a block 114 where a dielectric dummy layer 230 is deposited around the channel members 2080 and over the source/drain trenches 228. The dielectric dummy layer 230 may be an oxide, such as silicon oxide in some embodiments, and may be deposited using ALD, flowable chemical vapor deposition (FCVD), plasma enhanced chemical vapor deposition (PECVD), or other suitable deposition processes. The dielectric dummy layer 230 fills the space among the channel members 2080 and covers sidewalls of the channel members 2080. In the illustrated embodiment, in order to improve the gap fill capability without leaving voids thereunder, the deposition of the dielectric dummy layer 230 may include an ALD process to first form a thin dielectric layer and a subsequent FCVD process to form a thick dielectric layer over the thin dielectric layer. The combination of the ALD and FCVD processes improves gap fill capability without compromising production throughput.

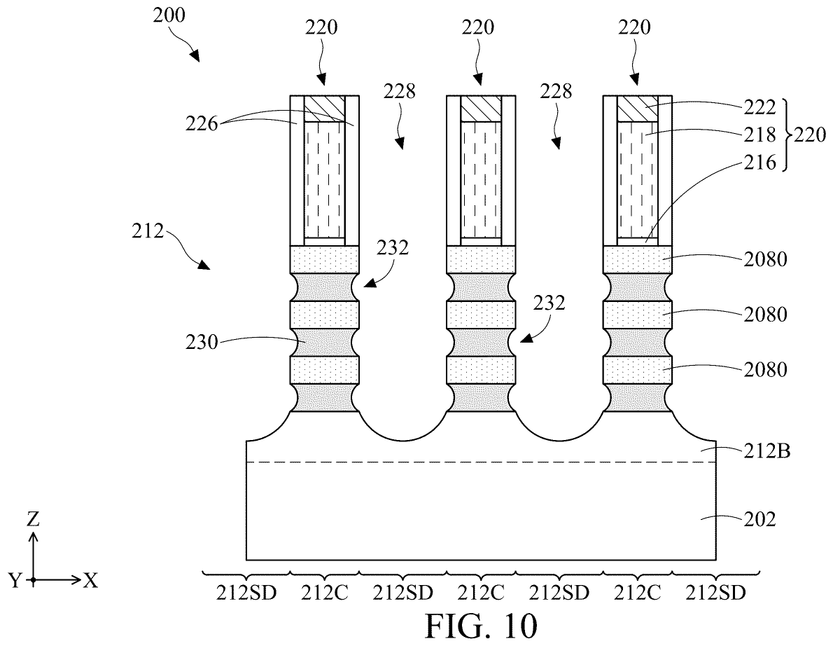

Referring to FIGS. 1 and 10, method 100 includes a block 116 where inner spacer recesses 232 are formed. The dielectric dummy layer 230 is selectively and partially recessed to form inner spacer recesses 232. The inner spacer recesses 232 may have a concave profile bending away from the source/drain trenches 228. In an embodiment, the selective recess of the dielectric dummy layer 230 may be performed using a selective wet etching process or a selective dry etching process. An example selective wet etching process may include use of diluted hydrofluoric acid (DHF) or a mixture of hydrofluoric acid (HF) and, ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. As shown in FIG. 10, the dielectric dummy layer 230 is removed from the source/drain regions 212SD, and the fin-shaped base 212B is exposed.

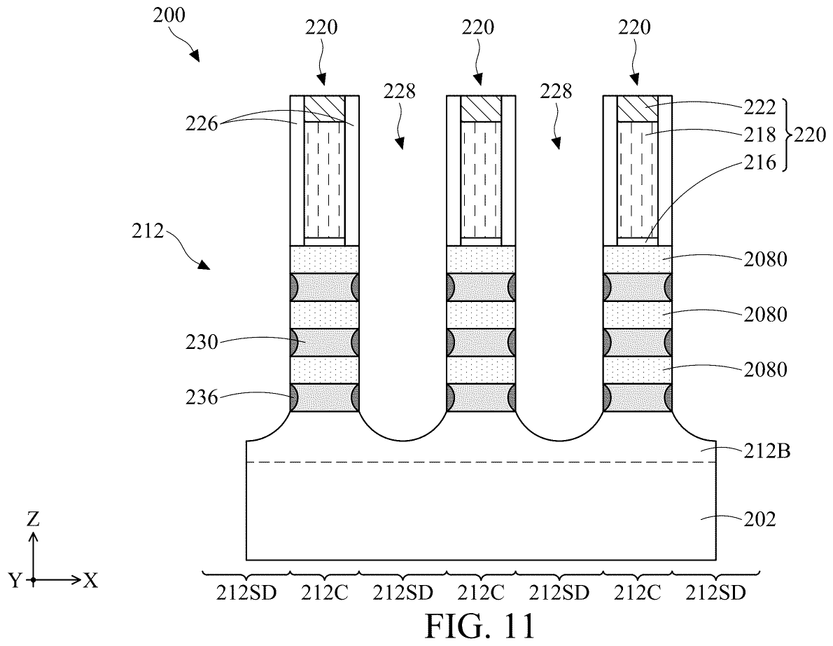

Referring to FIGS. 1 and 11, method 100 includes a block 118 where inner spacers 236 are formed in the inner spacer recesses 232. The formation of the inner spacers 236 may include the deposition of an inner spacer layer over exposed surfaces of the source/drain trenches 228, including filling the inner spacer recesses 232. A composition of the inner spacer layer is different from a composition of the dielectric dummy layer 230 to ensure that each one of them may be selectively etched without substantially damaging the other one. In some embodiments, the inner spacer layer may include silicon carbonitride (SiCN), silicon oxycarbonitride (SiOCN), silicon nitride (SiN), silicon oxycarbide (SiOC), or silicon oxynitride (SiON). In some implementations, the inner spacer layer may be deposited using CVD or ALD. Subsequently, the inner spacer layer is etched back to form inner spacers 236 in the inner spacer recesses 232. In some embodiments, the etching back of the inner spacer layer may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In the depicted embodiment, the inner spacers 236 substantially remain under the gate spacers 226 without extending to a position directly under the dummy gate stack 220. Alternatively, the inner spacers 236 may laterally extend to a position directly under the dummy gate stack 220.

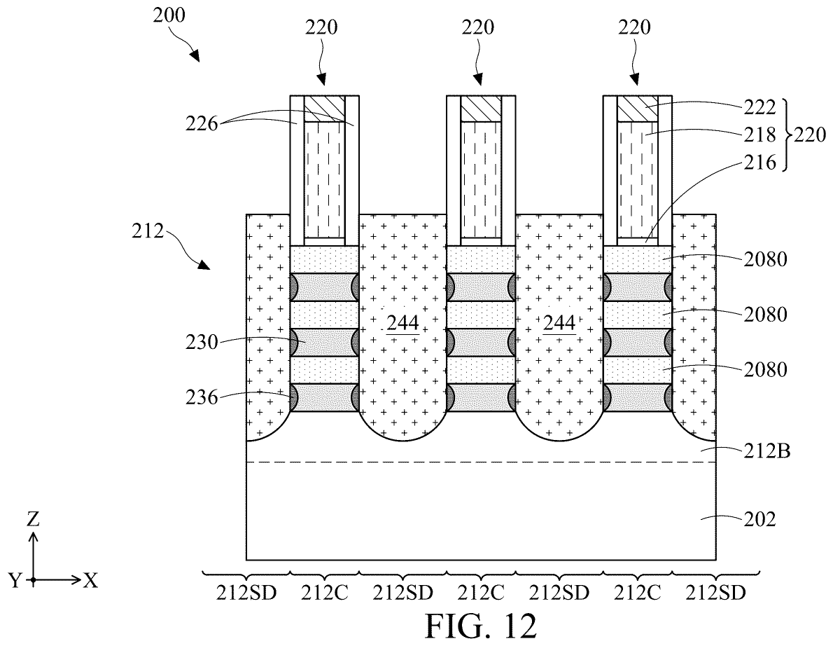

Referring to FIGS. 1 and 12, method 100 includes a block 120 where source/drain features 244 are epitaxially grown from the exposed semiconductor surfaces in the source/drain trenches 228, including from the sidewalls of the channel members 2080. The source/drain features 244 may be n-type or p-type. When the source/drain feature 244 is n-type, the source/drain feature 244 may include silicon (Si) and an n-type dopant, such as phosphorus (P), arsenic (As), antimony (Sb), or a combination thereof. When the source/drain feature 244 is p-type, the source/drain feature 244 may include silicon germanium (SiGe) and a p-type dopant, such as boron (B), boron difluoride (BF₂), or a combination thereof. While not explicitly shown in the figures, in some embodiments, the source/drain feature 244 may include multiple layers. For example, the source/drain feature 244 may include a buffer epitaxial layer that is dopant free, a lightly doped epitaxial feature over the buffer epitaxial layer, and a heavily doped epitaxial feature over the lightly doped epitaxial feature. The lightly doped epitaxial feature includes smaller dopant concentration and impurity concentration to reduce crystalline defects. The heavily doped epitaxial feature accounts for a majority of the volume to reduce contact resistance. The source/drain feature 244 may be formed using vapor-phase epitaxy (VPE), ultra-high vacuum CVD (UHV-CVD), or molecular beam epitaxy (MBE). Doping of the source/drain features 244 may be achieved with in-situ doping.

While not explicitly shown, before any of the epitaxial layers are formed, method 100 may include a cleaning process to clean surfaces of the semiconductor device 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment.

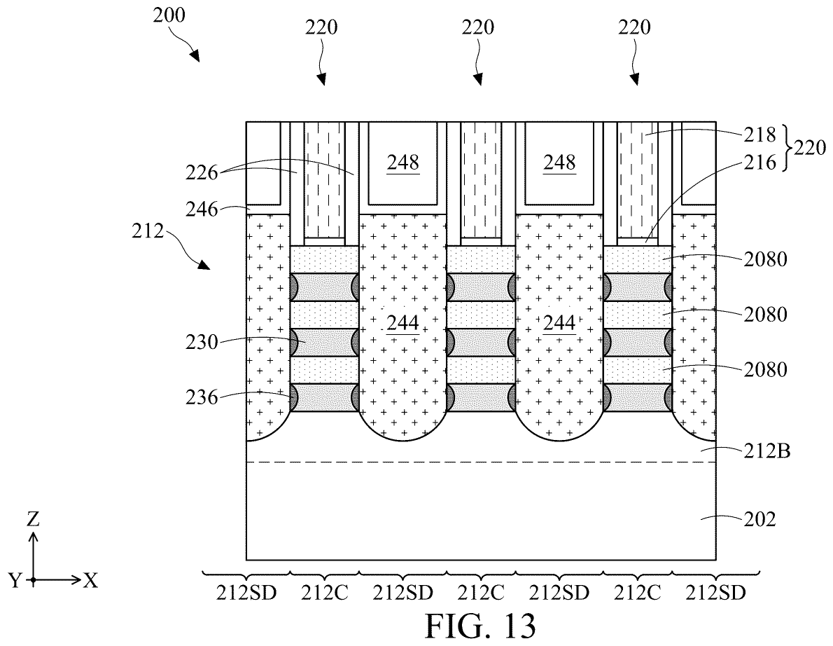

Referring to FIGS. 1 and 13-14, method 100 includes a block 122 where a contact etch stop layer (CESL) 246, an interlayer dielectric (ILD) layer 248, and a capping layer 249 are deposited in the source/drain regions 212SD. As shown in FIG. 13, the CESL 246 is deposited over the source/drain feature 244. The CESL 246 may include silicon nitride or aluminum nitride. In some implementations, the CESL 246 may be deposited using CVD or ALD. The ILD layer 248 is then deposited over the CESL 246. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the semiconductor device 200 may be planarized by a planarization process to remove the gate-top hard mask layer 222 and expose the dummy gate stack 220. For example, the planarization process may include a chemical mechanical planarization (CMP) process.

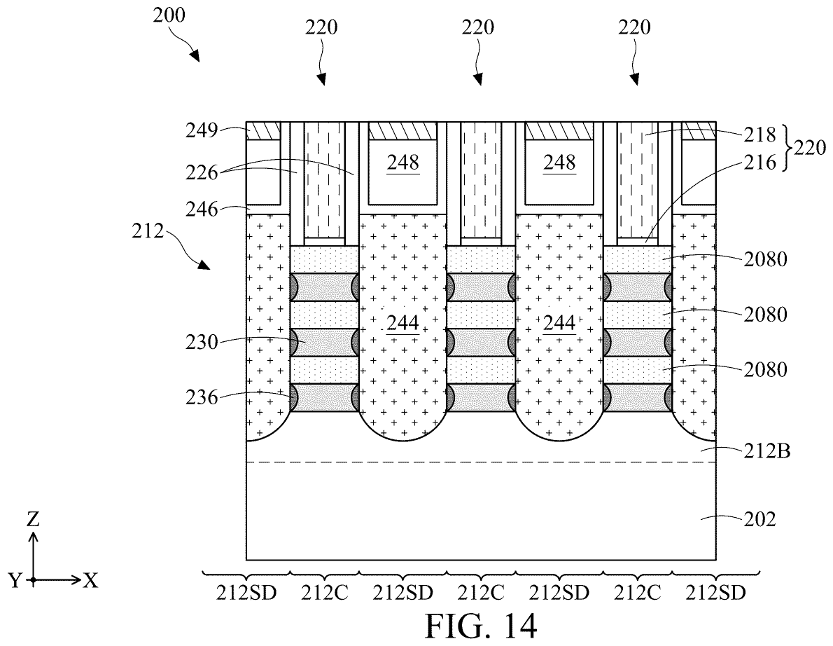

As shown in FIG. 14, in order to protect the ILD layer 248 from being damaged during the dielectric dummy layer 230 removal step, the ILD layer 248 is selectively recessed to form a top recess and a capping layer 249 is formed over the top recess. The capping layer 249 is formed of a different material than the dielectric dummy layer 230. When the dielectric dummy layer 230 includes silicon oxide, the capping layer 249 is not formed of silicon oxide so as to ensure etching selectivity. In some embodiments, the capping layer 249 may include silicon nitride, silicon carbonitride, silicon carbide, or silicon oxycarbonitride. In one embodiment, the capping layer 249 may include silicon nitride. Another planarization is performed to remove excess capping layer 249 and to expose the dummy gate stack 220. After the planarization, top surfaces of the capping layer 249, the CESL 246, the gate spacers 226, and the dummy gate stacks 220 are coplanar.

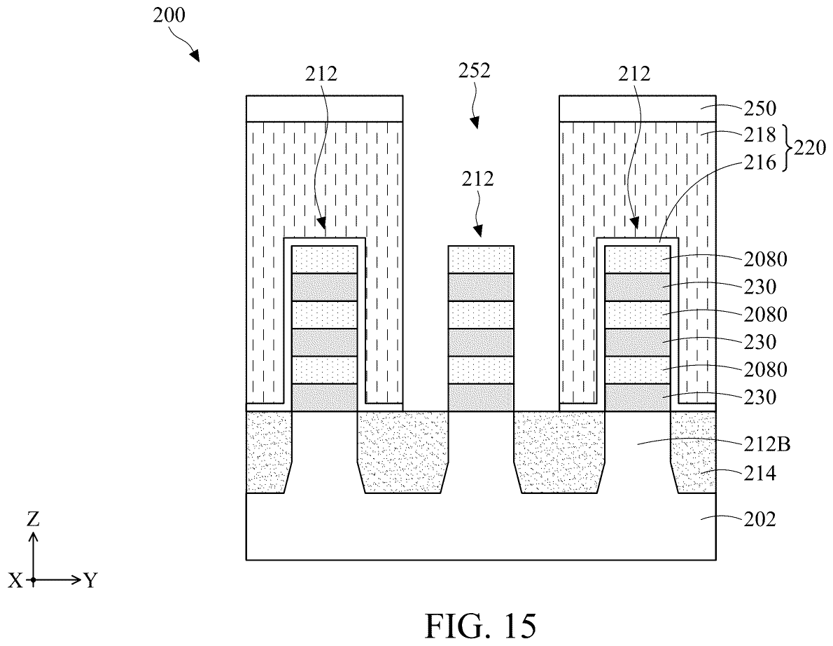

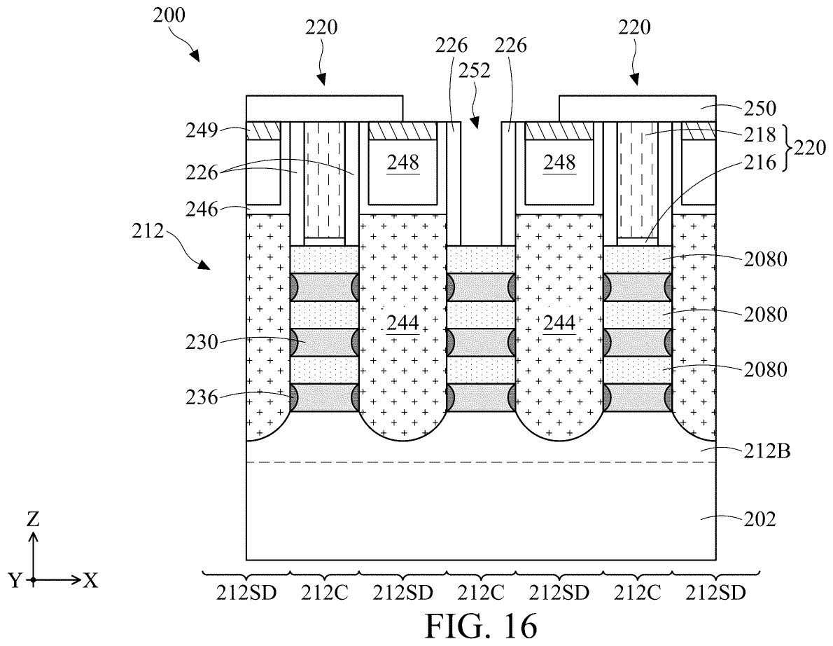

Referring to FIGS. 1 and 15-16, method 100 includes a block 124 where a portion of a dummy gate stack 220 is removed to form a trench 252. The removal of the dummy gate stack 220 may include one or more etching processes that are selective to the materials of the dummy gate stack 220. The removal of the dummy gate stack 220 is also referred to as a cut-poly (CPO) process, and the trench 252 is also referred to as a CPO trench 252. As shown in FIG. 15, a patterned mask layer 250 is formed over the semiconductor device 200 to expose a portion of the dummy gate stack 220. An etching process may be performed to selectively remove the exposed portion of the dummy gate stack 220. For example, the removal of the dummy gate stack 220 may be performed using as a selective wet etch, a selective dry etch, or a combination thereof that is selective to the dummy gate stack 220. As shown in FIG. 16, the etching selectivity between the dummy gate stack 220, the gate spacers 226, and the capping layer 249 allows the opening defined in the patterned mask layer 250 to not necessarily be strictly aligned with the sidewalls of the gate spacers 226, thereby enlarging process windows. After the performing of the etching process, a portion of the fin-shaped structure 212 in the channel region 212C that were previously covered by the dummy gate stack 220 is exposed.

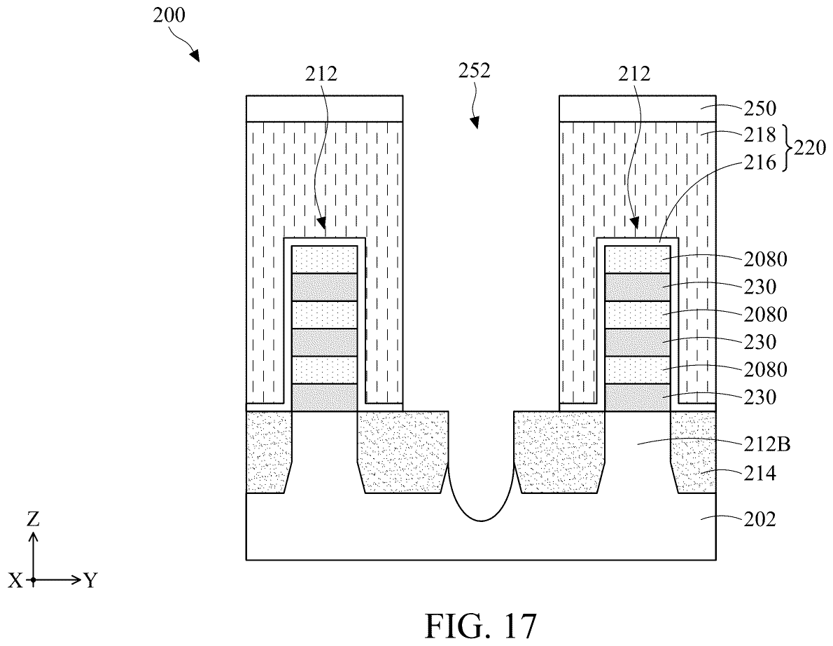

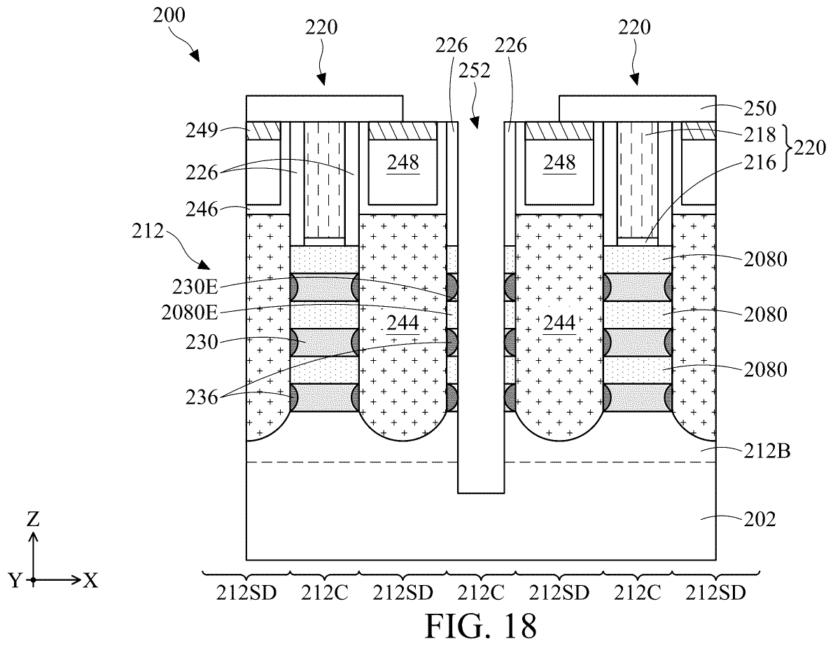

Referring to FIGS. 1 and 17-18, method 100 includes a block 126 where the exposed portion of the fin-shaped structure 212 is removed from the CPO trench 252. As a result, the CPO trench 252 further extends downward. An etching process may be performed to selectively remove the exposed portion of the fin-shaped structure 212. For example, the removal of the fin-shaped structure 212 may be performed using as a selective wet etch, a selective dry etch, or a combination thereof that is selective to the fin-shaped structure 212. In the present embodiment, the duration of the etching process is controlled such that the CPO trench 252 extends through the isolation feature 214 and extends into the substrate 202. As shown in FIG. 17, the isolation feature 214 remains substantially intact due to etching selectivity. Due to the tapering sidewall of the fin-shaped base 212B, a portion of the fin-shaped base 212B directly under the isolation feature 214 may remain. As shown in FIG. 18, the gate spacers 226 may protect a portion of the fin-shaped structure 212 directly under the gate spacers 226 from removing. The remaining portion of the fin-shaped structure 212 may include end portions of the channel members 2080 (denoted as semiconductor ends 2080E thereafter), end portions of the dielectric dummy layer 230 (denoted as dielectric ends 230E thereafter), and the inner spacers 236. If the inner spacers 236 do not laterally extend beyond sidewalls of the gate spacers 226, the inner spacers 236 remain as a whole, and the dielectric ends 230E cover the inner spacers 236 from exposing in the CPO trench 252; if the inner spacers 236 laterally extend beyond sidewalls of the gate spacers 226, the inner spacers 236 and the dielectric ends 230E are both exposed in the CPO trench 252. In some embodiments, the semiconductor ends 2080E include silicon, the dielectric ends 230E include silicon oxide, and the inner spacers 236 include silicon nitride. At the conclusion of block 126, the CPO trench 252 has an upper portion above the top surface of the isolation feature 214 that is wider than a lower portion below the top surface of the isolation feature 214.

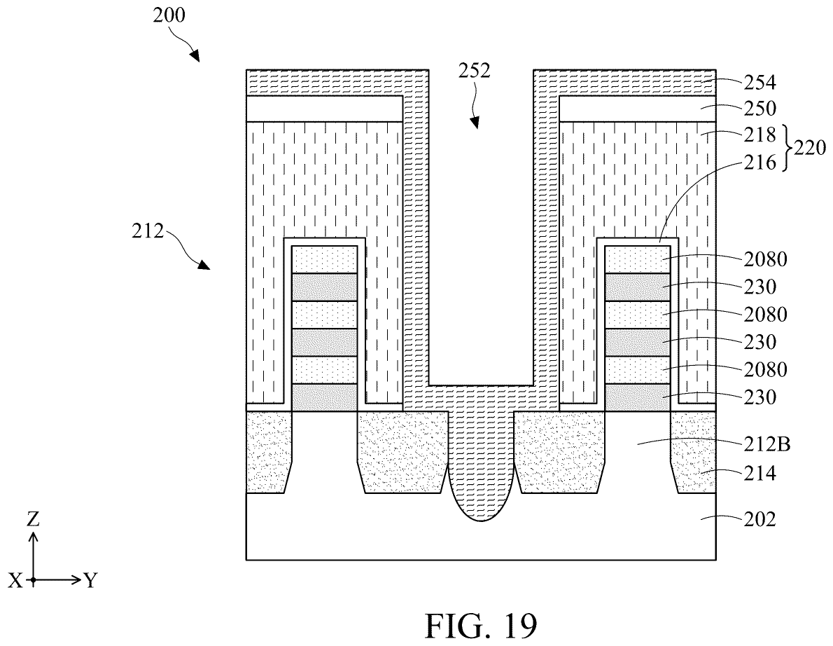

Referring to FIGS. 1 and 19, method 100 includes a block 128 where a first dielectric layer 254 is deposited in the CPO trench 252. In some embodiments, the first dielectric layer 254 is an oxide (e.g., silicon oxide). In the depicted embodiment, the first dielectric layer 254 substantially fills up the lower portion of the CPO trench 252. Depending on the deposition method, the first dielectric layer 254 may partially fill the upper portion of the CPO trench 252 or fully fill the upper portion of the CPO trench 252. For example, in the depicted embodiment as shown in FIG. 19, the first dielectric layer 254 is conformally deposited on sidewalls of the CPO trench 252, such as by an ALD process, until the layers in the lower portion of the CPO trench 252 merge, meanwhile the upper portion of the CPO trench 252 is partially filled with a reduced volume. Alternatively, the first dielectric layer 254 may substantially fill both the upper and lower portions of the CPO trench 252, such as by a CVD or PVD process.

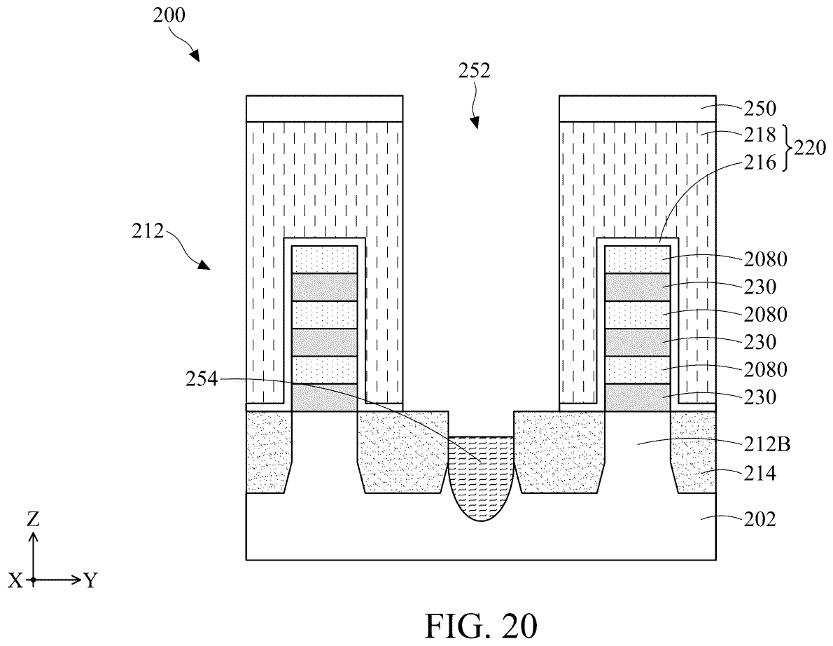

Referring to FIGS. 1 and 20, method 100 includes a block 130 where the first dielectric layer 254 is etched back to be lower than the top surface of the isolation feature 214. An etching process may be implemented to remove portions of the first dielectric layer 254 from the upper portion of the CPO trench 252. In some embodiments, the etching process may include dry etching (e.g., RIE etching), wet etching, and/or other etching methods. An example selective wet etching process may include use of diluted hydrofluoric acid (DHF) or a mixture of hydrofluoric acid (HF) and, ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. The patterned mask layer 250 protects other portions of the semiconductor device 200 from etching.

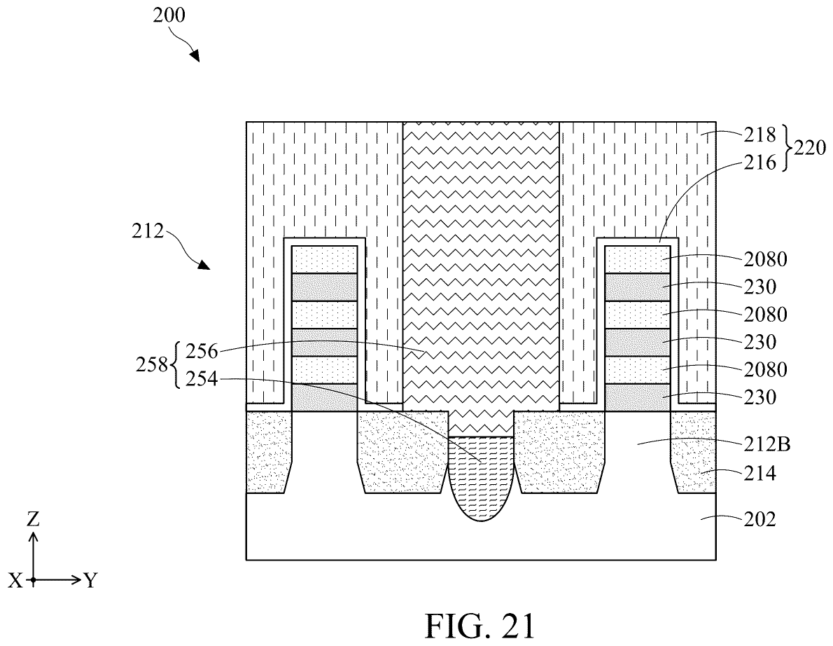

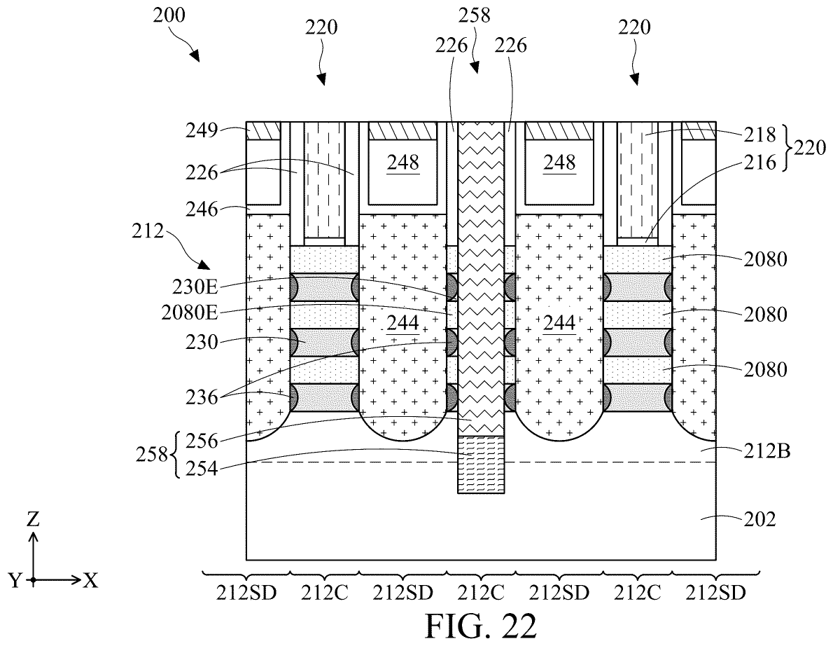

Referring to FIGS. 1 and 21-22, method 100 includes a block 132 where a second dielectric layer 256 is deposited in the CPO trench 252. The second dielectric layer 256 substantially fully fills the upper portion of the CPO trench 252 and a top part of the lower portion of the CPO trench 252. The first dielectric layer 254 and the second dielectric layer 256 collectively define an isolation feature 258. The isolation feature 258 is also referred to a CPO feature 258. In the depicted embodiment as shown in FIGS. 21 and 22, the CPO feature 258 is a bi-layer structure with an interface of the two dielectric materials below the top surface of the isolation feature 214. In some embodiments, the second dielectric layer 256 is free of oxygen, such as a nitride (e.g., silicon nitride or silicon carbonitride). The second dielectric layer may be deposited by ALD, CVD, PVD, or other suitable processes. As shown in FIG. 21, the CPO feature 258 divides the dummy gate stack 220 into two portions (or segments). The second dielectric layer 256 has an upper portion wider than its lower portion in the Y-Z plane. As shown in FIG. 22, the recessed top surface of the first dielectric layer 254 is still above the bottom surface of the source/drain feature 244. Alternatively, the recessed top surface of the first dielectric layer 254 may be below the bottom surface of the source/drain feature 244. Besides, in the CPO trench 252, the second dielectric layer 256 may have a substantially uniform width in the X-Z plane. At the conclusion of block 132, a planarization process (e.g., CMP) may be performed to remove excess portions of the second dielectric layer 256 and the patterned mask layer 250 to expose other dummy gate stacks 220.

Referring to FIGS. 1 and 23-24, method 100 includes a block 134 where the dummy gate stacks 220 are selectively removed. Exposure of the dummy gate stack 220 allows the removal thereof. The removal of the dummy gate stack 220 may include one or more etching processes that are selective to the materials of the dummy gate stack 220. For example, the removal of the dummy gate stack 220 may be performed using a selective wet etch, a selective dry etch, or a combination thereof that is selective to the dummy gate stack 220. The removal of the dummy gate stack 220 exposes the CPO feature 258, particularly its second dielectric layer 256, and the stacks of the channel members 2080 and the dielectric dummy layer 230.

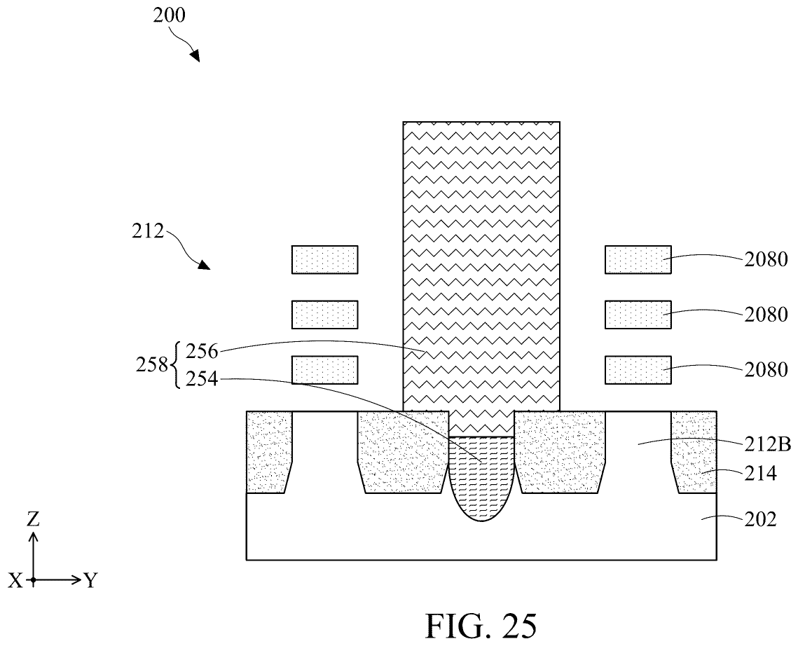

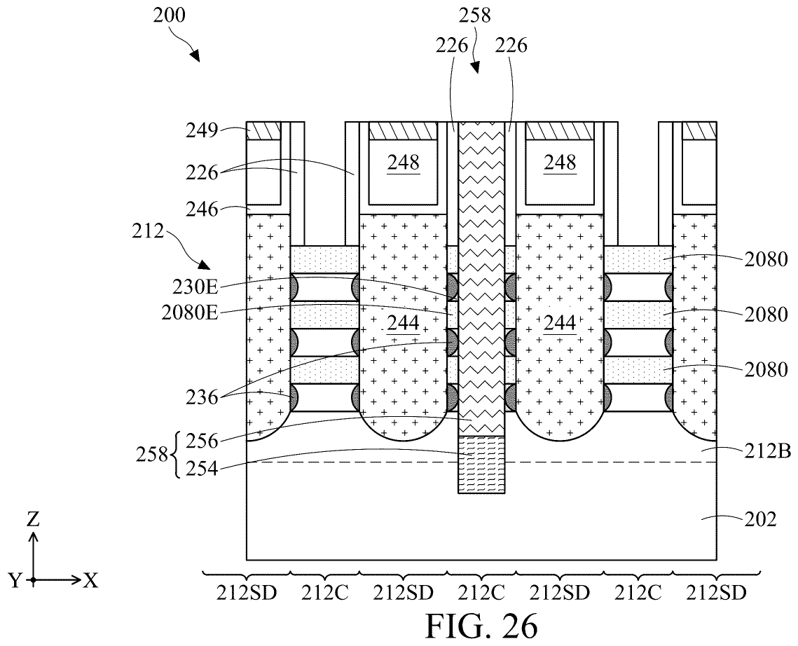

Referring to FIGS. 1 and 25-26, method 100 includes a block 136 where the dielectric dummy layer 230 is selectively removed from the channel regions 212C. After the removal of the dummy gate stack 220, the dielectric dummy layer 230 in the channel regions 212C is exposed and subsequently removed in a separate etching process. For example, a selective wet etching process or a selective dry etching process may be performed to remove the dielectric dummy layer 230. An example selective wet etching process may include use of diluted hydrofluoric acid (DHF) or a mixture of hydrofluoric acid (HF) and ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. By design, the etch selectivity of the dielectric dummy layer 230 over the channel members 2080 may be larger than about 1000:1, such that the channel members 2080 remain substantially intact. After the selective removal of the dielectric dummy layer 230, the channel members 2080 in the channel regions 212C are once again exposed. Since the channel members 2080 are protected from the etching process by a high etching contrast, a surface roughness of the channel members 2080 after being exposed may be less than about 0.5 nm. Notably, as shown in FIG. 26, the dielectric ends 230E in contact with the CPO feature 258 are not exposed to the etchants applied during the removal of the dielectric dummy layer 230 and remain in the semiconductor device 200. As shown in FIG. 25, if the first dielectric layer 254 of the CPO feature 258 is not recessed to below the top surface of the isolation feature 214, such as otherwise being a liner on sidewalls of the second dielectric layer 256, the removal of the dielectric dummy layer 230 would also remove the exposed portion of the first dielectric layer 254 and damage the CPO feature 258. A damaged CPO feature 258 may lead to metal gate protrusion and cause a short circuit between the subsequently-formed metal gate and adjacent source/drain contacts.

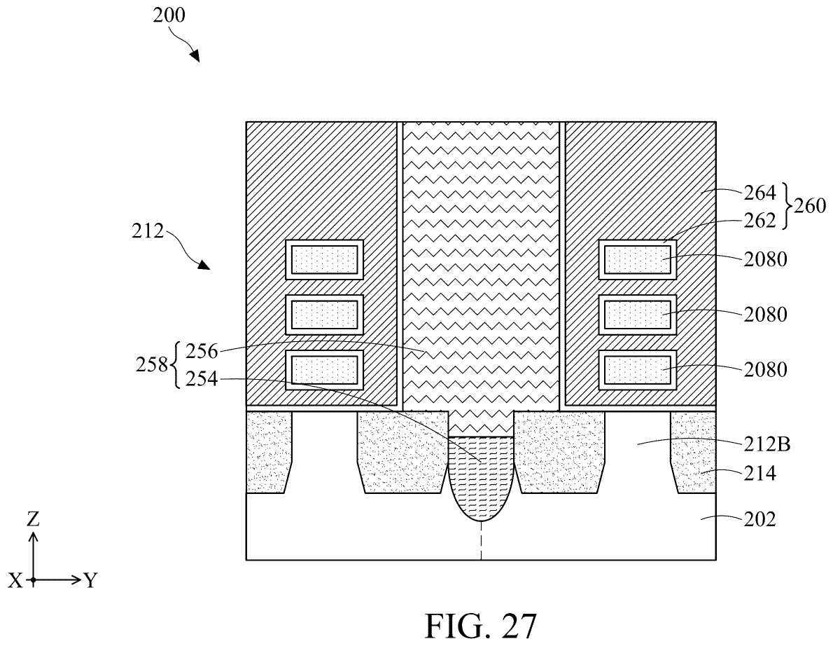

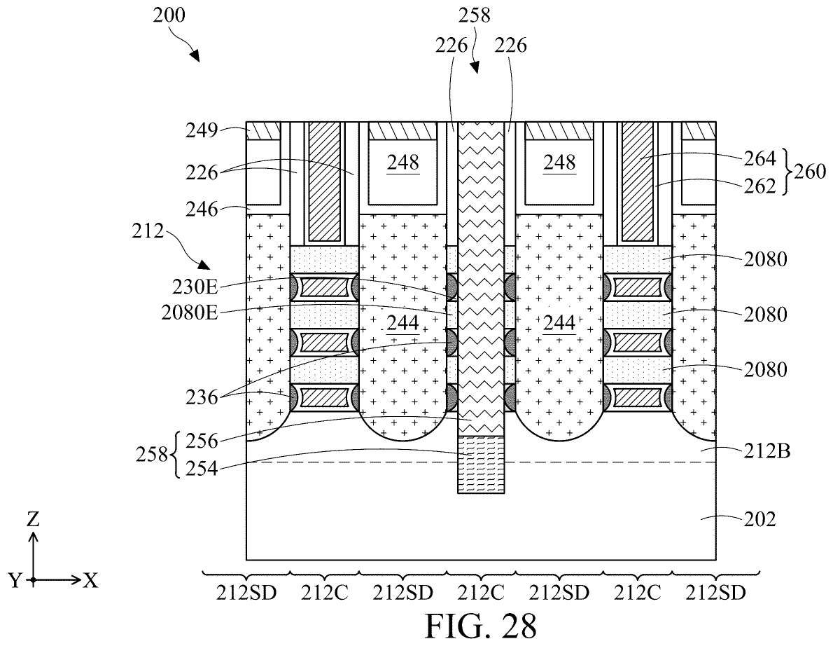

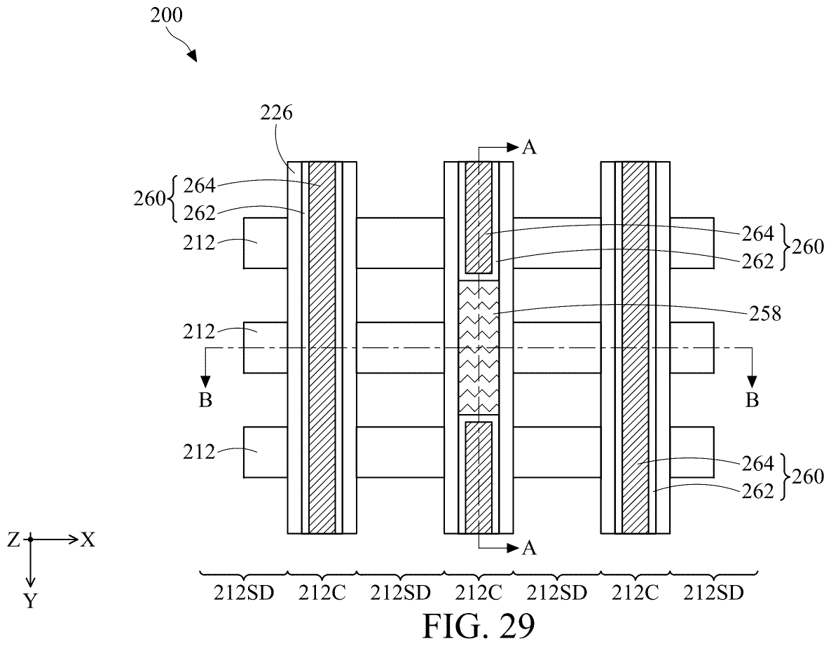

Referring to FIGS. 1 and 27-29, method 100 includes a block 138 where metal gate structure 260 is formed to wrap around each of the channel members 2080. FIG. 29 is a fragmentary top view of the semiconductor device 200 at the conclusion of block 138, FIG. 27 is a cross-sectional view along the A-A line in FIG. 29, and FIG. 28 is a cross-sectional view along the B-B line in FIG. 6. After the release of the channel members 2080, the metal gate structure 260 is formed to wrap around each of the channel members 2080. The gate structure 260 is also referred to as metal gate structure 260 due to its metal-containing layers. In the depicted embodiment, the gate structure 260 includes a gate dielectric layer 262 and a gate electrode layer 264 over the gate dielectric layer 262. Not explicitly shown, the gate dielectric layer 262 may further includes an interfacial layer interfacing the channel members 2080 and a high-k dielectric layer over the interfacial layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-k dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The high-k dielectric layer may be formed by ALD, physical vapor deposition (PVD), CVD, oxidation, and/or other suitable methods.

The gate electrode layer 264 of the gate structure 260 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 250c may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 250c may be formed by ALD, PVD, CVD, e-beam evaporation, or other suitable process. In various embodiments, a CMP process may be performed to remove excessive metal, thereby providing a substantially planar top surface of the gate structure. The gate structure 260 includes portions that interpose between channel members 2080 in the channel region 212C. In some embodiments, the gate structure 260 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

The portions of the gate structure 260 divided by the CPO feature 258 may each be referred to as a gate structure individually. Notably, as shown in FIG. 27, the two portions of the gate structure 260 disposed on two opposing sides of the CPO feature 258 may have opposite conductivity types, such as one being a p-type and another being an n-type. Correspondingly, the substrate 202 may be pre-doped with suitable dopants in forming an n-type well and a p-type well. A boundary between the n-type well and the p-type well is represented by a vertical dotted line in FIG. 27. The CPO feature 258, particularly the first dielectric layer 254, may be disposed above the boundary. The oxygen-containing first dielectric layer 254 extends into the top portion of the substrate 202 at the boundary, which helps to suppress accumulation of charges at the boundary between wells of opposite conductivity types. The suppression of charge accumulation at the boundary of the wells helps reducing leakage current in the substrate 202.

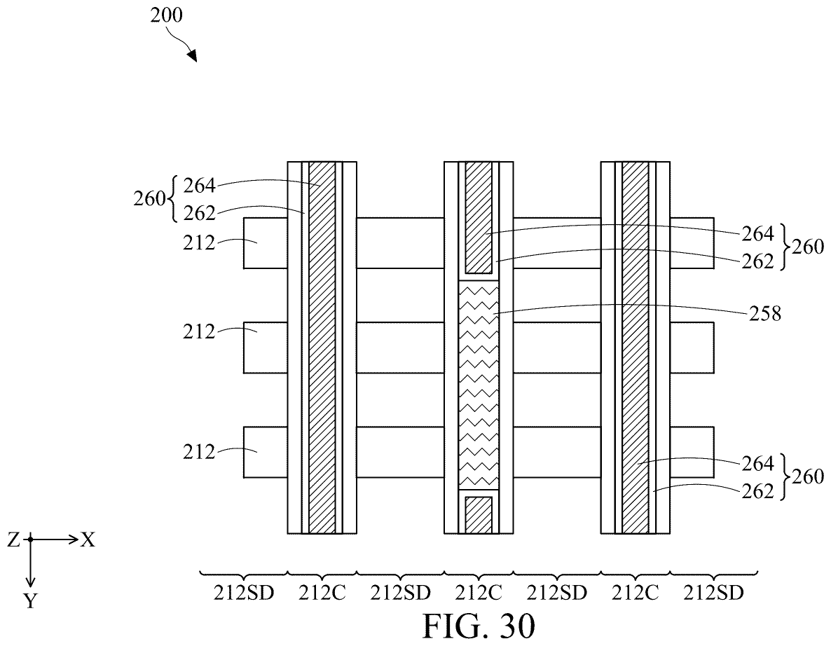

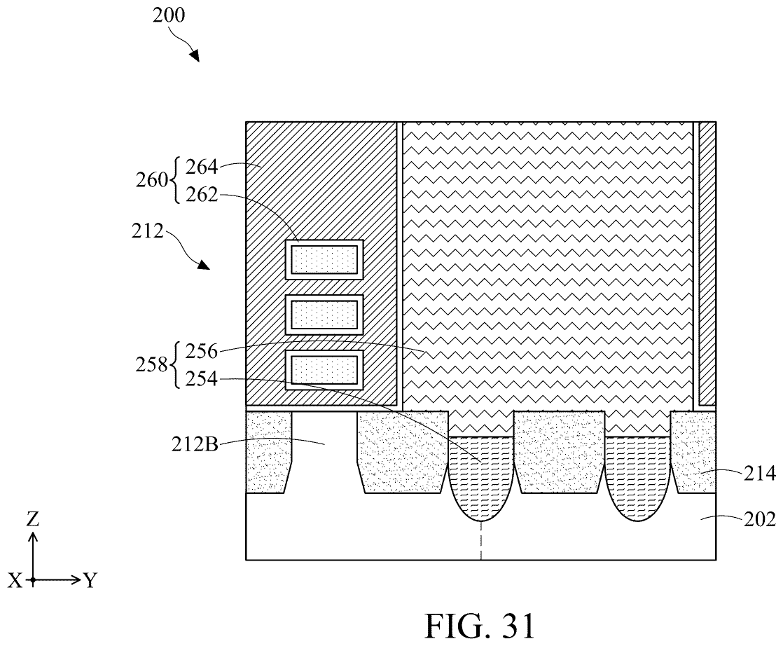

Reference is made to FIGS. 30 and 31, which illustrate an alternative embodiment of the CPO feature 258. FIG. 30 is a fragmentary top view of the semiconductor device 200 at the conclusion of block 138, FIG. 31 is a cross-sectional view along the A-A line in FIG. 30. As shown in FIG. 30, the CPO feature 258 crosses more than one active region 212. In the depicted embodiment, the CPO feature 258 crosses two active regions 212. Depending on application, the CPO feature 258 may cross three or more active regions 212 in various embodiments. As shown in FIG. 31, the CPO feature 258 includes an upper portion made of the second dielectric layer 256 and two lower portions made of the first dielectric layer 254.

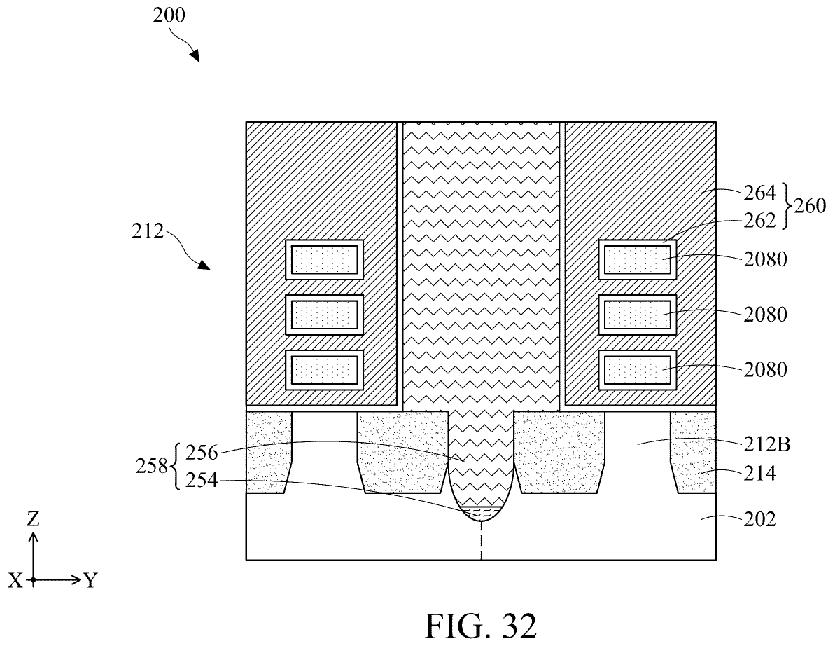

Reference is made to FIG. 32, which illustrates an alternative embodiment of the CPO feature 258. The recessed top surface of the first dielectric layer 254 of the CPO feature 258 may be lower than the bottom surface of the isolation feature 214. The enlarged volume of the second dielectric layer 256 may help reducing parasitic capacitance within the semiconductor device 200. In an embodiment, the second dielectric layer 256 includes a non-silicon based dielectric material, such as boron nitride (BN) that has a low dielectric constant about 2. In furtherance of an embodiment, the boron nitride (BN)-based second dielectric layer 256 includes boron nitride (BN) formed to have a hexagonal ring structure, thereby providing a sufficiently low dielectric constant. By extending the bottom surface of the second dielectric layer 256 below the bottom surface of the isolation feature 214, the parasitic capacitance within the semiconductor device 200 may be further reduced.

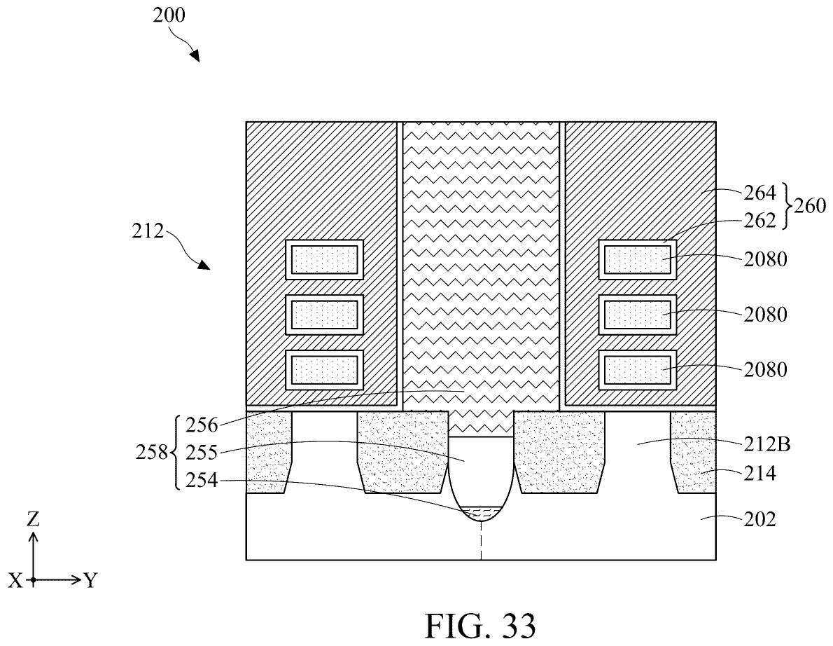

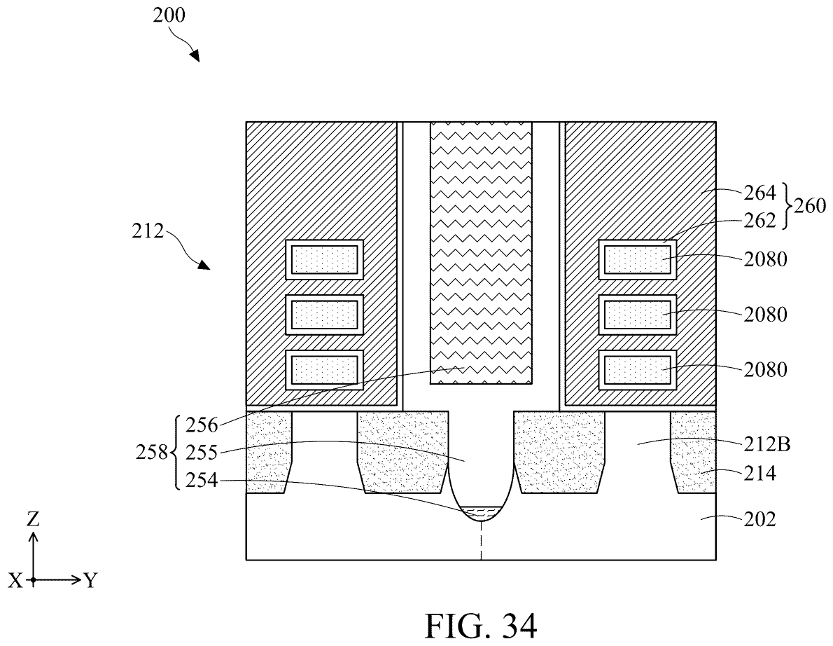

Reference is made to FIGS. 33 and 34, which illustrate alternative embodiments of the CPO feature 258. In the illustrated embodiment shown in FIG. 33, the CPO feature 258 is a tri-layer structure, which includes a bottom portion formed of the first dielectric layer 254, a top portion formed of the second dielectric layer 256, and a middle portion formed of a third dielectric layer 255. In one embodiment, the third dielectric layer 255 has a dielectric material composition different from the first dielectric layer 254 and the second dielectric layer 256. For example, the first dielectric layer 254 may include silicon oxide, the second dielectric layer may include silicon nitride, and the third dielectric layer may include silicon carbonitride. In another embodiment, the first dielectric layer 254 and the third dielectric layer 255 both include silicon oxide but differ in oxygen concentration. For example, oxygen concentration in the first dielectric layer 254 may be higher than in the third dielectric layer 255. When the third dielectric layer 255 contains oxygen, the top surface of the third dielectric layer 255 is recessed to below the top surface of the isolation feature 214. When the third dielectric layer 255 is free of oxygen (e.g., BN), the top surface of the third dielectric layer 255 may be below or above the top surface of the isolation feature 214. For example, the third dielectric layer 255 may be conformally deposited as a liner separating the second dielectric layer 256 from the gate dielectric layer 262, as shown in FIG. 34.

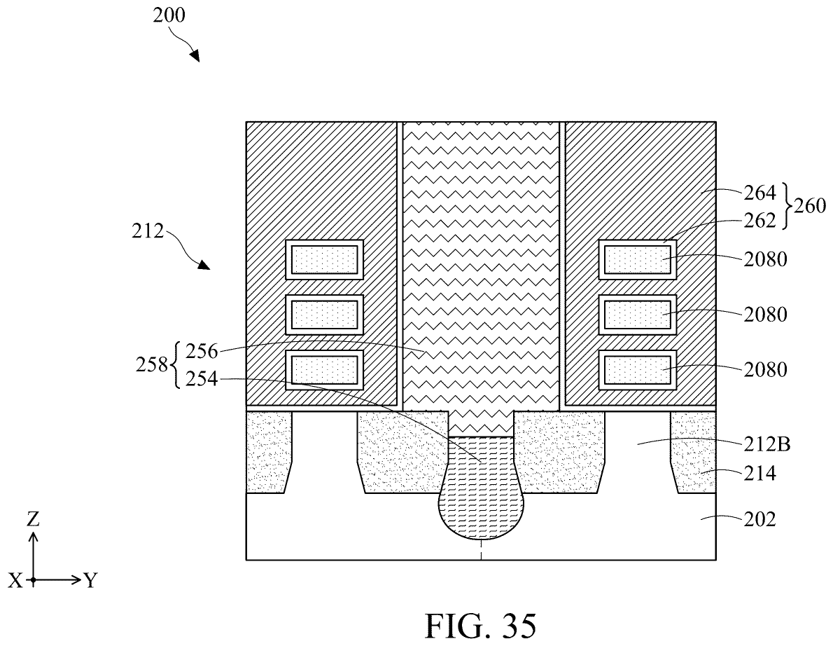

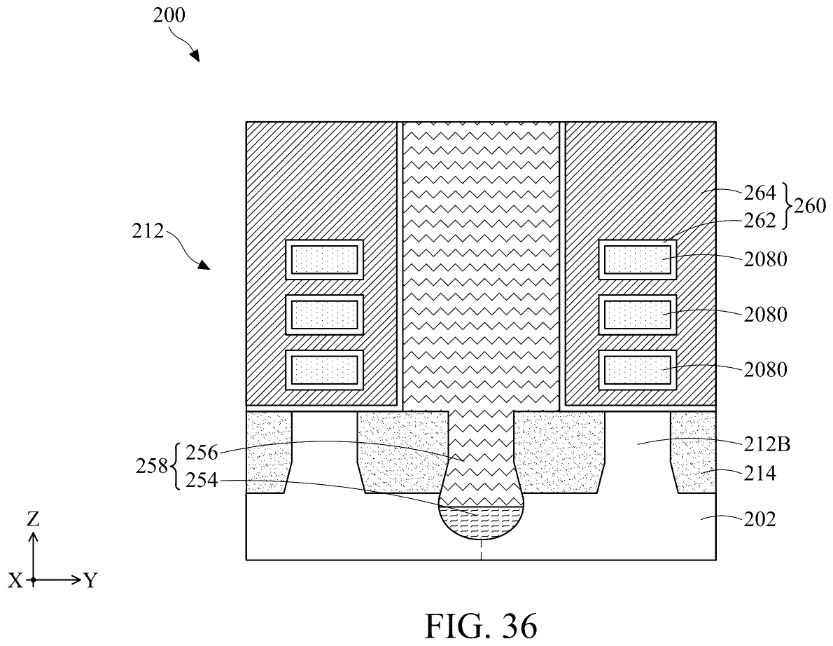

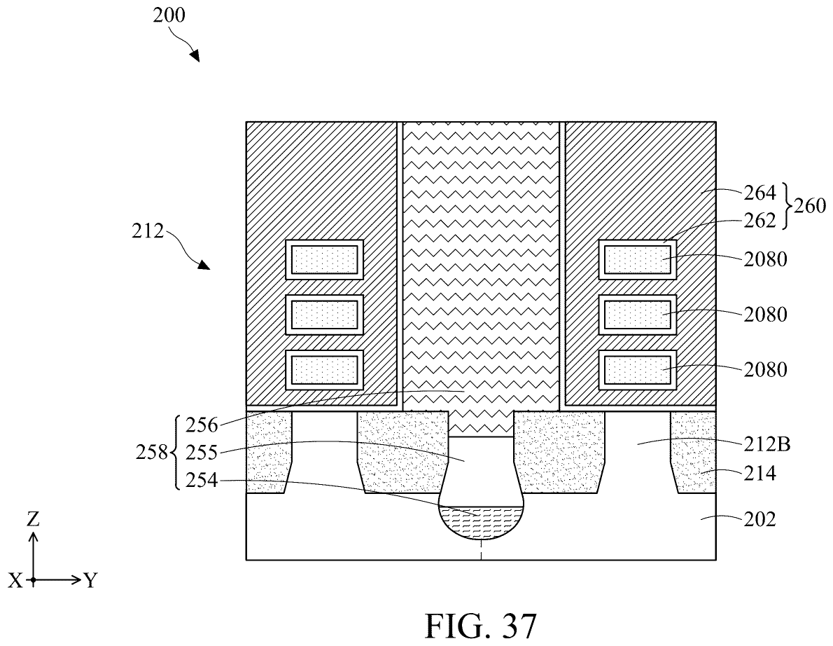

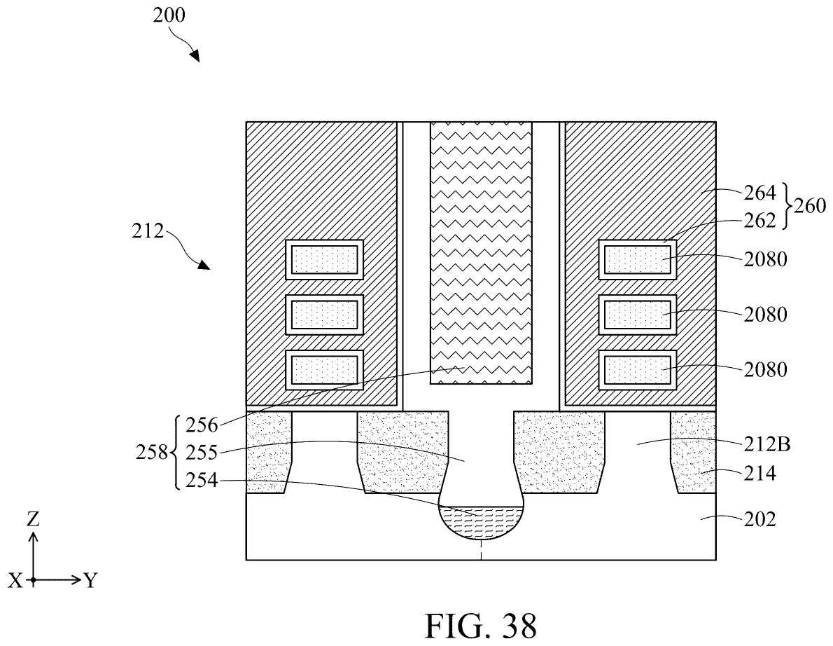

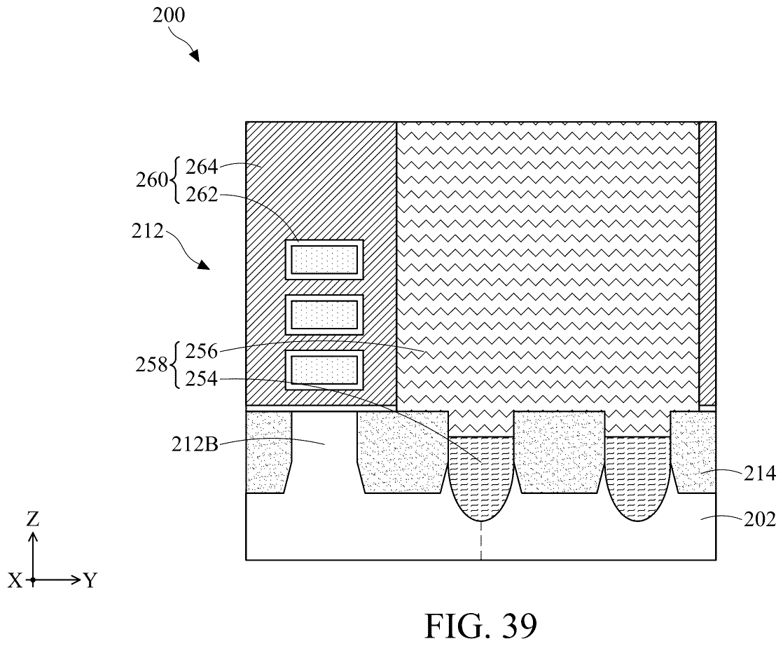

Reference is made to FIGS. 35-39, which illustrate alternative embodiments of the CPO feature 258. During the etching of the fin-shaped base 212B in extending the CPO trench 252 downward through the isolation feature 214, the tapering sidewall portion of the fin-shaped base 212B may also be etched and create an enlarged bottom portion of the CPO trench 252 below the bottom surface of the isolation feature 214. In FIG. 35, the CPO feature 258 is a bi-layer structure with the first dielectric layer 254 having an enlarged bottom portion. In FIG. 36, the CPO feature 258 is a bi-layer structure with the top surface of the first dielectric layer 254 being lower than the bottom surface of the isolation feature 214. In FIG. 37, the CPO feature 258 is a tri-layer structure with a third dielectric layer 255 stacked between the first dielectric layer 254 and the second dielectric layer 256. In FIG. 38, the CPO feature 258 is a tri-layer structure with a third dielectric layer 255 free of oxygen and conformally disposed between the second dielectric layer 256 and the gate dielectric layer 262. In FIG. 39, the CPO feature 258 may be alternatively formed after the replacement gate process, such that the CPO feature 258 is in direct contact with the gate electrode layer 264, as well as the gate dielectric layer 262, of the gate structure 260. The CPO feature 258 in previous discussed embodiments may also be alternatively formed after the replacement gate process and in direct contact with the gate electrode layer 264 and the gate dielectric layer 262.

Notably, various embodiments of the CPO feature 258 as depicted in FIGS. 32-38 may also be applied to the embodiment as depicted in FIG. 31. That is, if the CPO feature 258 crosses multiple active regions with multiple bottom portions extending downward from the bulk top portion, each of the bottom portions of the CPO feature 258 may implement the alternative embodiments as depicted in FIGS. 32-38.

Although not intended to be limiting, embodiments of the present disclosure provide one or more of the following advantages. For example, embodiments of the present disclosure replace germanium-containing sacrificial layers with oxide-containing dielectric dummy layers. During a replacement gate process, the dielectric dummy layers are selectively removed to release the channel members. A metal gate structure is then formed to wrap around each of the channel members. Such a process increases the etching contrast during the release of the channel members and improves the profile uniformity in the channel region of a GAA transistor. Further, an isolation structure is formed to separate different segments of the metal gate structure with an oxygen-containing bottom portion to suppress accumulation of charges at the boundary of wells of opposite conductivity types. The top surface of the oxygen-containing bottom portion of the isolation structure is purposefully positioned such that it would not be otherwise exposed and damaged during a replacement gate process. The embodiments of the present disclosure can be readily integrated into existing semiconductor manufacturing processes.

In one exemplary aspect, the present disclosure is directed to a method. The method includes forming a fin-shaped structure protruding from a substrate, depositing an isolation feature on sidewalls of the fin-shaped structure, forming a dummy gate stack over a portion of the fin-shaped structure, removing a portion of the dummy gate stack to form a trench exposing the portion of the fin-shaped structure, recessing the portion of the fin-shaped structure to extend the trench downward below a top surface of the isolation feature, depositing a first dielectric layer in the trench, recessing the first dielectric layer, such that a topmost portion of the first dielectric layer is below the top surface of the isolation feature, after the recessing of the first dielectric layer, depositing a second dielectric layer in the trench, the first and second dielectric layers including different material compositions, and replacing an unremoved portion of the dummy gate stack with a metal gate structure. In some embodiments, the first dielectric layer includes oxygen, and the second dielectric layer is free of oxygen. In some embodiments, the first dielectric layer is an oxide, and the second dielectric layer is a nitride. In some embodiments, the substrate includes two wells of opposite conductivity types, and the first dielectric layer is directly above a boundary between the two wells. In some embodiments, after the recessing of the portion of the fin-shaped structure, the trench is extended downward below a bottom surface of the isolation feature. In some embodiments, after the recessing of the first dielectric layer, the topmost portion of the first dielectric layer is below the bottom surface of the isolation feature. In some embodiments, the depositing of the first dielectric layer includes depositing the first dielectric layer on sidewalls of the unremoved portion of the dummy gate stack, and wherein the recessing of the first dielectric layer includes removing the first dielectric layer from the sidewalls of the unremoved portion of the dummy gate stack. In some embodiments, the fin-shaped structure includes a plurality of channel layers interleaved by a plurality of sacrificial layers, and the method further includes recessing a source/drain region of the fin-shaped structure to form a source/drain trench, selectively removing the sacrificial layers to release the channel layers, depositing a dielectric dummy layer in space between the channel layers, laterally recessing the dielectric dummy layer to form inner spacer recesses, forming inner spacers in the inner spacer recesses, and prior to the removing of the portion of the dummy gate stack, epitaxially growing a source/drain feature in the source/drain region. The dielectric dummy layer and the first dielectric layer both include oxygen. In some embodiments, the recessing of the portion of the fin-shaped structure exposes the inner spacers. In some embodiments, after the depositing of the second dielectric layer, an end portion of the dielectric dummy layer is in physical contact with the second dielectric layer.

In another exemplary aspect, the present disclosure is directed to a method. The method includes forming over a substrate a stack that includes a plurality of channel layers interleaved by a plurality of sacrificial layers, patterning the stack to form a fin-shaped structure, forming an isolation feature on sidewalls of the fin-shaped structure, forming a dummy gate stack over a first region of the fin-shaped structure and a top surface of the isolation feature, depositing gate spacers on sidewalls of the dummy gate stack, after the depositing of the gate spacers, recessing a second region of the fin-shaped structure outside of the dummy gate stack and the gate spacers to form a first trench, selectively removing the sacrificial layers in the first region to release the channel layers as channel members, depositing a dielectric dummy layer in space between adjacent two of the channel members, laterally recessing the dielectric dummy layer to form inner spacer recesses, depositing an inner spacer layer over the inner spacer recesses, etching back the inner spacer layer to form inner spacers in the inner spacer recesses, forming an epitaxial feature in the second region, after the forming of the epitaxial feature, removing a portion of the dummy gate stack to from a second trench exposing the first region of the fin-shaped structure, removing the first region of the fin-shaped structure from the second trench, depositing a first dielectric layer in the second trench, recessing the first dielectric layer, such that a top surface of the first dielectric layer is below the top surface of the isolation feature, depositing a second dielectric layer in the second trench and over the first dielectric layer, the first and second dielectric layers including different material compositions, and replacing an unremoved portion of the dummy gate stack with a metal gate structure. In some embodiments, the first dielectric layer is an oxygen-containing layer, and the second dielectric layer is an oxygen-free layer. In some embodiments, the second dielectric layer includes a bottom surface below the top surface of the isolation feature. In some embodiments, the substrate includes a first well of a first conductivity type and a second well of a second conductivity type that is opposite to the first conductivity type, and the first dielectric layer is directly above a boundary between the first and second wells. In some embodiments, the method further includes after the recessing of the first dielectric layer, depositing a third dielectric layer in the second trench. The second dielectric layer is above the third dielectric layer. In some embodiments, the method further includes recessing the third dielectric layer, such that a top surface of the third dielectric layer is below the top surface of the isolation feature.

In yet another exemplary aspect, the present disclosure is directed to a semiconductor structure. The semiconductor structure includes a plurality of channel members vertically stacked above a fin-shaped base protruding from a substrate, an isolation feature disposed on sidewalls of the fin-shaped base, a gate structure wrapping around each of the channel members, gate spacers disposed on sidewalls of the gate structure, a source/drain feature abutting the channel members and adjacent the gate structure, a plurality of inner spacers disposed between the source/drain feature and the gate structure, and an isolation structure abutting the gate structure. The isolation structure has a lower portion of a first dielectric material that contains oxygen and an upper portion of a second dielectric material that is oxygen-free, and a topmost portion of the first dielectric material is below a top surface of the isolation feature. In some embodiments, a bottommost portion of the first dielectric material is below a bottom surface of the isolation feature. In some embodiments, the substrate includes a first well of a first conductivity type and a second well of a second conductivity type that is opposite to the first conductivity type, and the isolation structure is directly above a boundary between the first and second wells. In some embodiments, the isolation structure has a middle portion of a third dielectric material, and a topmost portion of the third dielectric material is below the top surface of the isolation feature.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin-shaped structure protruding from a substrate;
depositing an isolation feature on sidewalls of the fin-shaped structure;
forming a dummy gate stack over a portion of the fin-shaped structure;
removing a portion of the dummy gate stack to form a trench exposing the portion of the fin-shaped structure;
recessing the portion of the fin-shaped structure to extend the trench downward below a top surface of the isolation feature;
depositing a first dielectric layer in the trench;
recessing the first dielectric layer, such that a topmost portion of the first dielectric layer is below the top surface of the isolation feature;
after the recessing of the first dielectric layer, depositing a second dielectric layer in the trench, the first and second dielectric layers including different material compositions; and
replacing an unremoved portion of the dummy gate stack with a metal gate structure.

2. The method of claim 1, wherein the first dielectric layer includes oxygen, and the second dielectric layer is free of oxygen.

3. The method of claim 2, wherein the first dielectric layer is an oxide, and the second dielectric layer is a nitride.

4. The method of claim 1, wherein the substrate includes two wells of opposite conductivity types, and wherein the first dielectric layer is directly above a boundary between the two wells.

5. The method of claim 1, wherein after the recessing of the portion of the fin-shaped structure, the trench is extended downward below a bottom surface of the isolation feature.

6. The method of claim 5, wherein after the recessing of the first dielectric layer, the topmost portion of the first dielectric layer is below the bottom surface of the isolation feature.

7. The method of claim 1, wherein the depositing of the first dielectric layer includes depositing the first dielectric layer on sidewalls of the unremoved portion of the dummy gate stack, and wherein the recessing of the first dielectric layer includes removing the first dielectric layer from the sidewalls of the unremoved portion of the dummy gate stack.

8. The method of claim 1, wherein the fin-shaped structure includes a plurality of channel layers interleaved by a plurality of sacrificial layers, the method further comprising:
recessing a source/drain region of the fin-shaped structure to form a source/drain trench;
selectively removing the sacrificial layers to release the channel layers;
depositing a dielectric dummy layer in space between the channel layers;
laterally recessing the dielectric dummy layer to form inner spacer recesses;
forming inner spacers in the inner spacer recesses; and
prior to the removing of the portion of the dummy gate stack, epitaxially growing a source/drain feature in the source/drain region,
wherein the dielectric dummy layer and the first dielectric layer both include oxygen.

9. The method of claim 8, wherein the recessing of the portion of the fin-shaped structure exposes the inner spacers.

10. The method of claim 8, wherein after the depositing of the second dielectric layer, an end portion of the dielectric dummy layer is in physical contact with the second dielectric layer.

11. A method, comprising:
forming over a substrate a stack that includes a plurality of channel layers interleaved by a plurality of sacrificial layers;
patterning the stack to form a fin-shaped structure;
forming an isolation feature on sidewalls of the fin-shaped structure;
forming a dummy gate stack over a first region of the fin-shaped structure and a top surface of the isolation feature;
depositing gate spacers on sidewalls of the dummy gate stack;
after the depositing of the gate spacers, recessing a second region of the fin-shaped structure outside of the dummy gate stack and the gate spacers to form a first trench;
selectively removing the sacrificial layers in the first region to release the channel layers as channel members;
depositing a dielectric dummy layer in space between adjacent two of the channel members;
laterally recessing the dielectric dummy layer to form inner spacer recesses;
depositing an inner spacer layer over the inner spacer recesses;
etching back the inner spacer layer to form inner spacers in the inner spacer recesses;
forming an epitaxial feature in the second region;
after the forming of the epitaxial feature, removing a portion of the dummy gate stack to from a second trench exposing the first region of the fin-shaped structure;
removing the first region of the fin-shaped structure from the second trench;
depositing a first dielectric layer in the second trench;
recessing the first dielectric layer, such that a top surface of the first dielectric layer is below the top surface of the isolation feature;
depositing a second dielectric layer in the second trench and over the first dielectric layer, the first and second dielectric layers including different material compositions; and
replacing an unremoved portion of the dummy gate stack with a metal gate structure.

12. The method of claim 11, wherein the first dielectric layer is an oxygen-containing layer, and the second dielectric layer is an oxygen-free layer.

13. The method of claim 11, wherein the second dielectric layer includes a bottom surface below the top surface of the isolation feature.

14. The method of claim 11, wherein the substrate includes a first well of a first conductivity type and a second well of a second conductivity type that is opposite to the first conductivity type, and wherein the first dielectric layer is directly above a boundary between the first and second wells.

15. The method of claim 11, further comprising:
after the recessing of the first dielectric layer, depositing a third dielectric layer in the second trench, wherein the second dielectric layer is above the third dielectric layer.

16. The method of claim 15, further comprising:
recessing the third dielectric layer, such that a top surface of the third dielectric layer is below the top surface of the isolation feature.

17. A semiconductor structure, comprising:
a plurality of channel members vertically stacked above a fin-shaped base protruding from a substrate;
an isolation feature disposed on sidewalls of the fin-shaped base;
a gate structure wrapping around each of the channel members;
gate spacers disposed on sidewalls of the gate structure;
a source/drain feature abutting the channel members and adjacent the gate structure;
a plurality of inner spacers disposed between the source/drain feature and the gate structure; and
an isolation structure abutting the gate structure,
wherein the isolation structure has a lower portion of a first dielectric material that contains oxygen and an upper portion of a second dielectric material that is oxygen-free, and a topmost portion of the first dielectric material is below a top surface of the isolation feature.

18. The semiconductor structure of claim 17, wherein a bottommost portion of the first dielectric material is below a bottom surface of the isolation feature.

19. The semiconductor structure of claim 17, wherein the substrate includes a first well of a first conductivity type and a second well of a second conductivity type that is opposite to the first conductivity type, and wherein the isolation structure is directly above a boundary between the first and second wells.

20. The semiconductor structure of claim 17, wherein the isolation structure has a middle portion of a third dielectric material, and wherein a topmost portion of the third dielectric material is below the top surface of the isolation feature.
